(19) United States
(12) Patent Application Publication
(10) Pub. No.: US 2023/0408395 A1
(43) Pub. Date: Dec. 21, 2023

(54) SYSTEM AND METHOD FOR PNEUMATIC-FREE ELECTRONICALLY DRIVEN MICROFLUIDICS TO ALLOW MASSIVE SCALABILITY WITH INTEGRATED CELLULAR AND BIOMOLECULAR DETECTION

(71) Applicant: The Trustees of Princeton University, Princeton, NJ (US)

(72) Inventors: Chengjie ZHU, Jersey City, NJ (US); Jesus Manuel Maldonado VAZQUEZ, Princeton, NJ (US); Hao TANG, Princeton, NJ (US); Kaushik SENGUPTA, Princeton, NJ (US)

(73) Assignee: The Trustees of Princeton University, Princeton, NJ (US)

(21) Appl. No.: 18/037,931

(22) PCT Filed: Nov. 19, 2021
(86) PCT No.: PCT/US2021/060021

§ 371 Date: May 19, 2023

Related U.S. Application Data
(60) Provisional application No. 63/116,226, filed on Nov. 20, 2020.

(51) Int. Cl. G01N 15/10

(52) U.S. Cl. CPC G01N 15/1031; G01N 15/1056; G01N 2015/1075; G01N 2015/1006

(57) ABSTRACT

According to various embodiments, a microfluidic bio-sensing system is disclosed. The system includes at least one semiconductor chip configured to control at least one of electrokinetic fluid flow, cell manipulation and sensing, and bio-molecular sensing by utilizing at least one plurality of electrodes in a microfluidic channel. The bio-sensing system is applicable to general bio-molecular and cell-based diagnostics in a battery-powered hand-held ultra-compact packaging without requiring any external instrumentations, allowing for the elimination of pneumatic pumps.

### CROSS-REFERENCE TO RELATED APPLICATIONS

This application claims priority to provisional application 63/116,226, filed Nov. 20, 2020, which is herein incorporated by reference in its entirety.

### STATEMENT REGARDING FEDERALLY SPONSORED RESEARCH OR DEVELOPMENT

This invention was made with government support under Grant No. ECCS-1711067 awarded by the National Science Foundation. The government has certain rights in the invention.

### FIELD OF THE INVENTION

The present invention relates generally to point of care (POC) systems and more particularly to bulk fluid processing with AC-osmotic based electrokinetic fluid flows that can be controlled, processed, and automated with integrated cellular and biomolecular detections for POC diagnostics.

### BACKGROUND OF THE INVENTION

The widespread nature of the COVID-19 pandemic has demonstrated the importance of POC diagnostics that allow an end-to-end biosensing capability from bio-sample to diagnostic information. Bridging this sample-to-information paradigm requires addressing two broad and equally important objectives that need to satisfy sensitivity and specificity requirements necessary for POC applications while also being low cost.

The first objective is to automate the first step in the biosensing process that involves extracting and processing the relevant bio-samples (cells/molecules) from the sample selectively. Such sample preparation can involve several steps including dissolution and mixing with several reagents, dilution, and filtering, all of which are critical to the robustness of the assay chemistry, sensing sensitivity, and specificity.

The second step involves the detection of desired substances (cells and molecules of interest) in the processed sample. In the past decade, there have been significant efforts in enabling such low-cost sensing devices. These include quantitative platforms using complementary metal-oxide-semiconductor (CMOS) based integrated circuit technology. Several modalities of bio-molecular sensing including fluorescence-based, magnetic-based, label-free sensing have been demonstrated in prior works across both nucleic acid and protein-based assays. For cells, cytometry has also been demonstrated with magnetic-labels or in a label-free manner.

However, sample fluid preparation is still typically done either manually or with an array of pressure-driven microfluidic channels, connected through a set of tubes to syringe pumps. As a result, while the sensing interface is miniaturized, the rest of the POC system can still be bulky and expensive, thereby severely liming its range of application. In the case of ingestible-based electronics for in-vivo sensing, such pressure driven flow is even more impractical, given the ultra-miniaturized nature of the entire sensing system. Therefore, electronically driven flow becomes attractive to consider for ultra-compact biosensing applications, given its scalability and compatibility with the chip-scale sensing interfaces. While electrically driven droplets and molecular and cell manipulation techniques, such as electro-wetting, electrophoresis, and dielectrophoresis, have been demonstrated in singular systems, these systems do not have the capability to process bulk bio-sample fluids that is required for POC systems.

### SUMMARY OF THE INVENTION

According to various embodiments, a microfluidic bio-sensing system is disclosed. The system includes at least one semiconductor chip configured to control at least one of electrokinetic fluid flow, cell manipulation and sensing, and bio-molecular sensing by utilizing at least one plurality of electrodes in a microfluidic channel. The semiconductor chip can be configured to control voltage magnitudes on either side of the electrodes to synthesize an electric field in the microfluidic channel for electrokinetic fluid flow. The semiconductor chip can be further configured to control voltage magnitudes on either side of the microfluidic channel to synthesize an electric field in the microfluidic channel for cell focusing. The semiconductor chip can be also configured to create an asymmetric excitation on the plurality of electrodes for cell separation. A top portion of the plurality of electrodes can be designated for voltage excitation and a bottom portion of the plurality of electrodes can be connected to a receiver for cell sensing. Further, a first portion of the plurality of electrodes can be designated for voltage excitation and a second portion of the plurality of electrodes can be connected to a receiver for bio-molecular sensing, where some electrodes of the plurality of electrodes are activated with probe molecules for binding with molecules of interest.

According to various embodiments, a scalable bio-sensing system is disclosed. The system includes an array of microfluidic controllers, where each controller includes at least one semiconductor chip configured to control at least one of electrokinetic fluid flow, cell manipulation and sensing, and bio-molecular sensing by utilizing at least one plurality of electrodes in a microfluidic channel. A semiconductor chip of at least one of the microfluidic controllers is configured to control voltage magnitudes on either side of the plurality of electrodes to synthesize an electric field in the microfluidic channel for electrokinetic fluid flow. A semiconductor chip of at least one of the microfluidic controllers is configured to control voltage magnitudes on either side of the microfluidic channel to synthesize an electric field in the microfluidic channel for cell focusing. A semiconductor chip of at least one of the microfluidic controllers is configured to create an asymmetric excitation on the plurality of electrodes for cell separation. In at least one of the microfluidic controllers, a top portion of the plurality of electrodes is designated for voltage excitation and a bottom portion of the plurality of electrodes is connected to a receiver for cell sensing. In at least one of the microfluidic controllers, a first portion of the plurality of electrodes is designated for voltage excitation and a second portion of the plurality electrodes is connected to a receiver for bio-molecular sensing, where some electrodes of the plurality of electrodes are activated with probe molecules for binding with molecules of interest.

According to various embodiments, a microfluidic bio-sensing system is disclosed. The system includes at least one semiconductor chip configured to control electrokinetic fluid flow, cell manipulation and sensing, and bio-molecular sensing by utilizing pluralities of electrodes in a microfluidic channel. The semiconductor chip is configured to control voltage magnitudes on either side of the electrodes to synthesize an electric field in the microfluidic channel for electrokinetic fluid flow. The semiconductor chip is further configured to control voltage magnitudes on either side of the microfluidic channel to synthesize an electric field in the microfluidic channel for cell focusing. The semiconductor chip is also configured to create an asymmetric excitation on the plurality of electrodes for cell separation. A top portion of the plurality of electrodes is designated for voltage excitation and a bottom portion of the plurality of electrodes is connected to a receiver for cell sensing. Further, a first portion of the plurality of electrodes is designated for voltage excitation and a second portion of the plurality of electrodes is connected to a receiver for bio-molecular sensing, where some electrodes of the plurality of electrodes are activated with probe molecules for binding with molecules of interest.

Various other features and advantages will be made apparent from the following detailed description and the drawings.

### BRIEF DESCRIPTION OF THE DRAWINGS

In order for the advantages of the invention to be readily understood, a more particular description of the invention briefly described above will be rendered by reference to specific embodiments that are illustrated in the appended drawings. Understanding that these drawings depict only exemplary embodiments of the invention and are not, therefore, to be considered to be limiting its scope, the invention will be described and explained with additional specificity and detail through the use of the accompanying drawings, in which:

FIG. 1 depicts a CMOS-based microfluidics and biosensing system that combines CMOS driven scalable microfluidics with controlled AC-osmotic based flow, cell manipulation, sensing, and separation through dynamic electric field yield synthesis, and impedance spectroscopy for cytometry and biomolecular sensing according to an embodiment of the present invention;

FIG. 2(a) depicts a microscopic view of the electrode-electrolyte double layers interface according to an embodiment of the present invention;

FIG. 2(b) depicts a corresponding electric potential profile showing exponentially decreasing potential in the diffusion layer according to an embodiment of the present invention;

FIG. 3(a) depicts operating principles of induced-charge AC electro-osmosis showing current paths between the asymmetric electrodes through double-layer capacitor and bulk fluid resistances according to an embodiment of the present invention;

FIG. 3(b) depicts operating principles of induced-charge AC electro-osmosis showing an equivalent circuit model between the asymmetric electrodes under AC excitation according to an embodiment of the present invention;

FIG. 3(c) depicts operating principles of induced-charge AC electro-osmosis showing ionic motion in diffusion layer on the larger electrode during the positive cycle of AC excitation, showing that the net ionic motion points from the larger to smaller electrode irrespective of the AC cycle, according to an embodiment of the present invention;

FIG. 3(d) depicts operating principles of induced-charge AC electro-osmosis showing an illustration of AC electro-osmosis demonstrating the unidirectional flow can be generated through asymmetric electrode designs and AC excitation voltages according to an embodiment of the present invention;

FIG. 4(a) depicts cell manipulation through dynamic electric field engineering through an array of electrodes showing dielectrophoretic (DEP) force exerting on the beads/cells, with negative DEP (nDEP) force direction defined as pointing towards low electric field intensity and vice versa for positive DEP (pDEP), according to an embodiment of the present invention;

FIG. 4(b) depicts cell manipulation through dynamic electric field engineering through an array of electrodes showing an illustration of DEP combined with microfluidic channel according to an embodiment of the present invention;

FIG. 5(a) depicts electric field synthesis for cell manipulation showing a system of electrodes containing cell focusing (7 pairs), sensing (4 pairs), and separation (7 pairs) functionalities according to an embodiment of the present invention;

FIG. 5(b) depicts electric field synthesis for cell manipulation showing an illustration of four possible DEP operating conditions: excitation signals are turned off, balanced excitation signals are fed into the two sides of electrodes, imbalanced signal is activated, and only one side of the electrodes are activated, according to an embodiment of the present invention;

FIG. 6 depicts a variation of f_{CM} as a function of electric field frequency for red blood cells where fluid medium conductivity and dielectric constant is set to 60 mS m⁻¹ and 78 ∈₀, respectively, and the conductivity and dielectric properties are set at 310 mS m⁻¹ and 59 ∈₀, respectively, according to an embodiment of the present invention;

FIG. 7 depicts an impedance sensing architecture based on direct-conversion where core components include voltage excitation, impedance sensing electrodes, TIA, down-conversion mixer, and low-pass filters according to an embodiment of the present invention;

FIG. 8(a) depicts fabricated fluidic system and electrodes showing fabricated gold electrodes on glass substrate, containing AC osmosis bulk fluid driving and system of DEP actuation and impedance sensing electrodes and microfluidic channel made of PDMS is permanently bonded on top of glass substrate, according to an embodiment of the present invention;

FIG. 8(b) depicts fabricated fluidic system and electrodes showing a zoomed view of 100 pairs of asymmetric AC osmosis electrodes according to an embodiment of the present invention;

FIG. 8(c) depicts fabricated fluidic system and electrodes showing a zoomed view of the system electrodes, containing cell focusing, sensing, and separation electrodes, according to an embodiment of the present invention;

FIG. 9(a) depicts a microfluidic assembly showing a side view of the fully assembled electrode channel interface according to an embodiment of the present invention;

FIG. 9(b) depicts a microfluidic assembly showing a zoomed view of the electrode-glass interface with gold electrodes deposited on top of chrome as adhesive layer according to an embodiment of the present invention;

FIG. 10(a) depicts AC-osmosis and DEP driver architecture and circuits showing architecture of the DEP and AC osmosis driving chip, capable of generating 5-9 V of driving signals at HV driver outputs for DEP according to an embodiment of the present invention;

FIG. 10(b) depicts AC-osmosis and DEP driver architecture and circuits showing on-chip programmable square wave generator according to an embodiment of the present invention;

FIG. 10(c) depicts AC-osmosis and DEP driver architecture and circuits showing 3.3 V level shifter according to an embodiment of the present invention;

FIG. 11 depicts a high-voltage (HV) level-shifter and driver, using stacked topology capable of generating safely 5-9 V of driving signals for DEP, according to an embodiment of the present invention;

FIG. 12(a) depicts receiver architecture for impedance spectroscopy showing 16-array architecture (4 dedicated for cell sensing and 12 for on-chip protein sensing) containing the excitation and receiver paths according to an embodiment of the present invention;

FIG. 12(b) depicts receiver architecture for impedance spectroscopy showing passive double-balanced mixer according to an embodiment of the present invention;

FIG. 12(c) depicts receiver architecture for impedance spectroscopy showing on-chip I and Q clock generator from a single ×2 LO frequency according to an embodiment of the present invention;

FIG. 13 depicts constant-gm biasing with start-up circuit to prevent V_{bias} been latched to V_{dd} according to an embodiment of the present invention;

FIG. 14(a) depicts noise analysis in the receiver path showing TIA and mixer noise according to an embodiment of the present invention;

FIG. 14(b) depicts noise analysis in the receiver path showing VGA noise according to an embodiment of the present invention;

FIG. 14(c) depicts noise analysis in the receiver path showing LPF noise according to an embodiment of the present invention;

FIG. 15 depicts a table of transfer function of major noise sources in LPF to LPF output according to an embodiment of the present invention;

FIG. 16(a) depicts CMOS-based pneumatic-free microfluidic and biosensing platform showing a front view of the system showing the fluidic interface and the AC-osmotic and DEP control chip according to an embodiment of the present invention;

FIG. 16(b) depicts CMOS-based pneumatic-free microfluidic and biosensing platform showing a back view of system showing the impedance sensing chip according to an embodiment of the present invention;

FIG. 16(c) depicts CMOS-based pneumatic-free microfluidic and biosensing platform showing die photo of the CMOS chips for impedance sensing, AC osmosis, and DEP cell actuation according to an embodiment of the present invention;

FIG. 16(d) depicts CMOS-based pneumatic-free microfluidic and biosensing platform showing PCB system schematic for the impedance sensing according to an embodiment of the present invention;

FIG. 16(e) depicts CMOS-based pneumatic-free microfluidic and biosensing platform showing AC osmosis and DEP driving circuitries according to an embodiment of the present invention;

FIG. 17 depicts a measured input-referred current noise in comparison with simulated and modeled results according to an embodiment of the present invention;

FIG. 18 depicts linearity and gain measurements showing a measured TIA gain of 91.4 dBΩ and 1-dB output compression at 16.8 μA according to an embodiment of the present invention;

FIG. 19 depicts a table of comparisons with state-of-the-art CMOS impedance cell cytometry and protein sensing system according to an embodiment of the present invention;

FIG. 20 depicts a high-voltage output waveform of the DEP HV driver ranging from 5-8V of output swing according to an embodiment of the present invention;

FIG. 21(a) depicts AC-osmotic flow measurements showing a zoomed view of the AC osmosis electrode geometry according to an embodiment of the present invention;

FIG. 21(b) depicts AC-osmotic flow measurements showing AC osmosis electrode geometry according to an embodiment of the present invention;

FIG. 21(c) depicts AC-osmotic flow measurements showing dimensions for different electrode geometries according to an embodiment of the present invention;

FIG. 21(d) depicts AC-osmotic flow measurements showing AC osmosis velocity characterization among three different electrode patterns, demonstrating a top velocity of 160 μm/s achieved with 18 Vpp excitation for pattern #1 according to an embodiment of the present invention;

FIG. 22(a) depicts AC-osmotic flow measurements showing measurement location for the AC osmosis showing relative to entire glass substrate according to an embodiment of the present invention;

FIG. 22(b) depicts AC-osmotic flow measurements showing a zoomed view of the two floating electrodes with 1 μm beads flowing on top of them according to an embodiment of the present invention;

FIG. 22(c) depicts AC-osmotic flow measurements showing bulk fluid velocity characterizations for pattern #1 under excitation frequencies according to an embodiment of the present invention;

FIG. 22(d) depicts AC-osmotic flow measurements showing bulk fluid velocity characterizations for pattern #1 under PBS concentrations according to an embodiment of the present invention;

FIG. 23(a) depicts DEP focusing performance characterization showing focusing performance is quantified by measuring vertical positions of the beads/cells passing at the end of the focusing electrodes where best DEP focusing performance can be reached under balanced excitation of 14 Vpp, with cells being center focused in the channel and an error of 2 μm according to an embodiment of the present invention;

FIG. 23(b) depicts DEP focusing performance characterization showing DEP separation characterization showing by activating only the top electrodes with 14 Vpp nearly 100% of the cells are separated into the correct channel according to an embodiment of the present invention;

FIG. 24(a) depicts cell-sensing measurements showing measured real-time sensing results for a 10 μm bead flow according to an embodiment of the present invention;

FIG. 24(b) depicts cell-sensing measurements showing, for larger beads of size 20 μm, a signal level of 8 mV is measured when the bead flows away from the electrode according to an embodiment of the present invention;

FIG. 24(c) depicts cell-sensing measurements showing real-time measurement of yeast cell according to an embodiment of the present invention;

FIG. 25(a) depicts label-free bio-molecular sensing measurements showing protein measurement electrode platform with 3 mm diameter for the center excitation electrode and 1 mm diameter for the TIA input electrodes according to an embodiment of the present invention;

FIG. 25(b) depicts label-free bio-molecular sensing measurements showing measured cytolysin target protein according to an embodiment of the present invention; and

FIG. 25(c) depicts label-free bio-molecular sensing measurements showing an illustration of surface chemistry developed for the Cytolysin protein detection, following standard self-assembled monolayer (SAM) bio-assay protocol according to an embodiment of the present invention.

### DETAILED DESCRIPTION OF THE INVENTION

The importance of point-of-care (POC) biomolecular diagnostics capable of rapid analysis has become abundantly evident after the outbreak of the Covid-19 pandemic. While sensing interfaces for both protein and nucleic-acid based assays have been demonstrated with chip-scale systems, sample fluid preparation has often been a major bottleneck in enabling end-to-end diagnostics. Typically, such sample handling is either done manually, or through a complex array of microfluidic channels, the flow being precisely controlled via pressure in complex tubing through bulky syringe pumps. Miniaturization of an end-to-end system requires addressing the front-end sample processing, without which, the goal for low-cost POC diagnostics remain elusive.

As such, addressed herein are bulk fluid processing with AC-osmotic based electrokinetic fluid flows that can be fully controlled, processed, and automated by complementary metal-oxide-semiconductor (CMOS) integrated circuits (ICs), allowing large scalability. Here, bulk fluid flow controls are combined with bio-molecular sensing, cell manipulation, cytometry, and separation, all of which are controlled with silicon chips for an all-in-one biosensing device. Shown herein are CMOS controlled pneumatic-free bulk fluid flow with fluid velocities reaching up to 160 μm/s within a microfluidic channel of 100×50 μm² of cross-sectional area. Dynamic engineering of electric fields is incorporated with electrode arrays to precisely control and electronically focus cell flows for robust cytometry and subsequent separation. A 16-array impedance spectroscopy receiver is also incorporated for cell and label-free protein sensing. The massive scalability of CMOS-driven microfluidics, manipulation, and sensing can lead to a new design space and a new class of miniaturized sensing technologies.

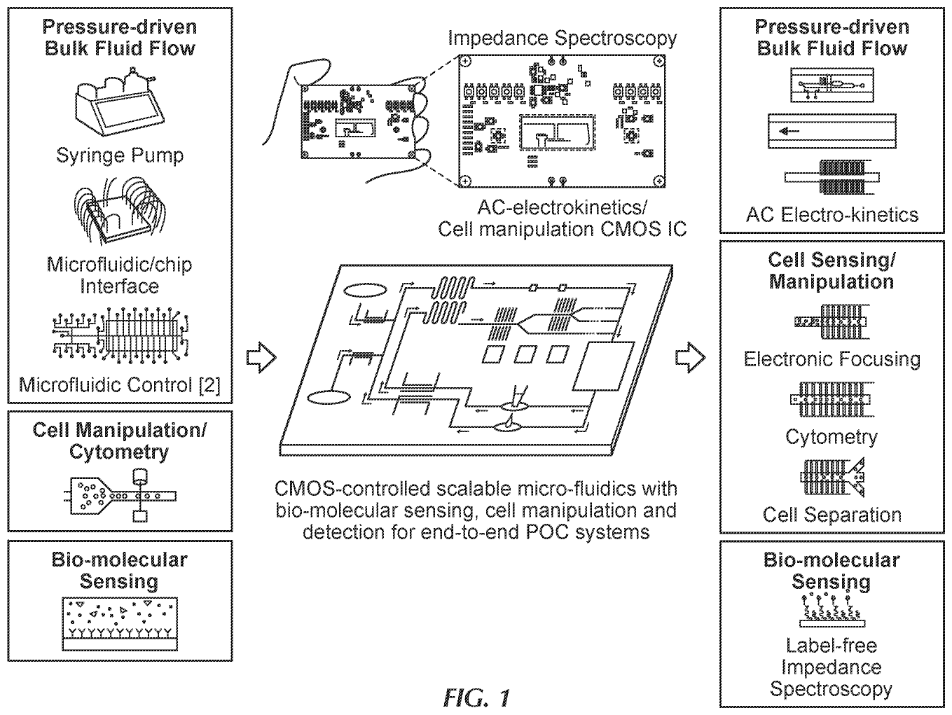

Generally disclosed herein are embodiments for a system and method involving a CMOS-based bio-sensing approach that combines the functionalities of bulk fluid processing and cellular/bio-molecular sensing capabilities in a single handheld platform, as shown generally by FIG. 1. Demonstrated herein is a CMOS-microfluidic bio-sensing system that is capable of 1) driving bulk electrolyte fluid with AC electro-osmosis, 2) cell manipulation and separation with dynamic electric field manipulations through an array of electrodes, and 3) cytometry and label-free bio-molecular sensing with 16-element integrated impedance spectroscopic receivers. While these kernel functionalities are demonstrated in a multi-chip module, the overall architecture, microfluidics, and sensing components can be massively scaled up for various POC applications due to elimination of pressure-driven flows.

Electrokinetics: AC Osmotic Bulk Fluid Flow with CMOS ICs

Pneumatic-based microfluidic flow with syringe pumps is challenging to scale up due to the complexity and increasing number of pneumatic pumps and microfluidic tubing required for sample preparation in biosensing systems. Electrokinetics can provide a scalable solution through controlling of ionic fluids with electric fields. Here, AC osmosis allows scalable electrolyte motion with voltage levels supported by CMOS ICs.

Fundamentals of Electro-Osmotic Flow

Electro-osmosis provides one of the most popular non-pressure driven flows in microfluidics. The basic principle of the nonlinear flow generated by electro-osmosis relies on a charged electrode that creates non-neutral ionic layers at the electrode-electrolyte interface. Within the interface, a cloud of charged particles creates a diffusion layer, which under the influence of an external electric field, drags the polarizable water molecule tangential to the electrode surface causing the bulk fluid motion.

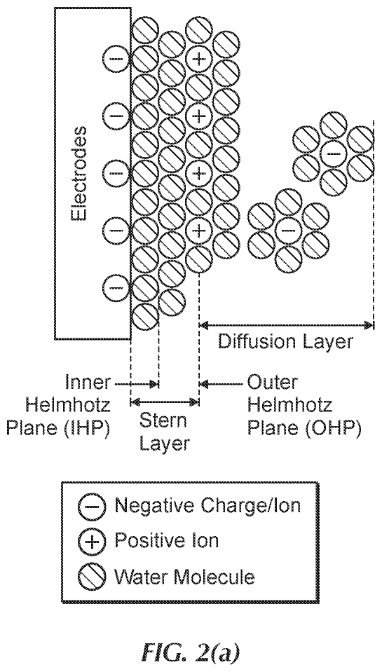

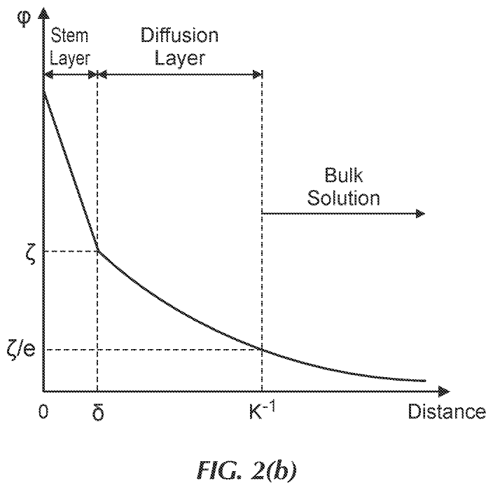

The principle for the electrodes that create the desired osmotic flow, therefore, focuses on engineering the optimal electric fields that generate the nonlinear drag to allow net fluid flow in one direction. When a charged electrode surface comes in contact to an ionic solution, an electrode double layer forms. FIGS. 2(a)-(b) demonstrate a microscopic view at the electrode-electrolyte double layer interface. Close to the electrode, a tightly bound stem layer forms including an inter (IHP) and outer Helmholtz plane (OHP). Beyond the tightly bound stern layer, the potential decreases exponentially creating a cloud of charges that attract the polarizable water molecules, known as the diffusion layer. The exponentially decreasing potential profile can be modeled through Debye-Huckle theory approximation. In addition, due to the non-uniform charge distribution, there exists a net electric field in the double layer, which can be modeled with an equivalent capacitance, C_{DL}. The value of the capacitance per unit area is inversely proportional to the diffusion length (κ⁻¹), where κ² given by

$${κ}^{2} = \frac{{q}^{2}}{ϵ {k}_{B} T} [ \sum {n}_{i} {z}_{i}^{2} ] ,$$

and q is the charge of a single electron, ∈ is the dielectric constant of the medium, k_{B} is Boltzmann's constant, T is temperature in kelvin, nᵢ represents the number of charges for each ion type in a unit volume and zᵢ is the valency of each ion. As an example, in 0.001×PBS solution, the debye length contributed by the dominated ions, Na+ and Cl− (≈0.137 mM for each ion), alone is roughly around 20-30 nm.

In summary, the various principles of the electro-osmosis can be itemized as follows:

(1) Ions in the diffusion layer attract the polarizable water molecules. Therefore, by moving the ions in the diffusion layer, there will be a drag effect on the water molecules that eventually lead to bulk fluid motion.

(2) Manipulation of the ions in the diffusion layer can be realized by creating tangential electric fields close to the electrode surface.

(3) Presence of ions is necessary for such fluid motion. Many bio-samples (blood/saliva/sweat) are ionic, and therefore, such techniques are applicable.

AC Electro-Osmotic Flow

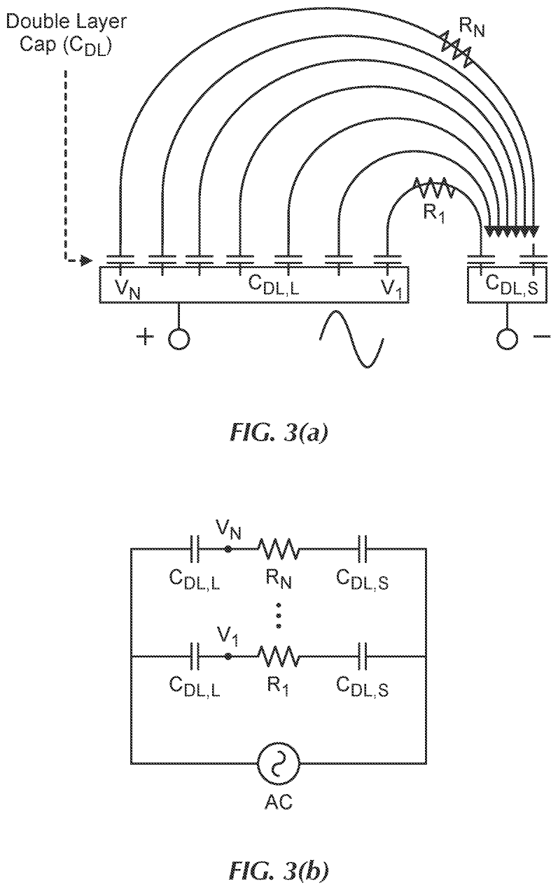

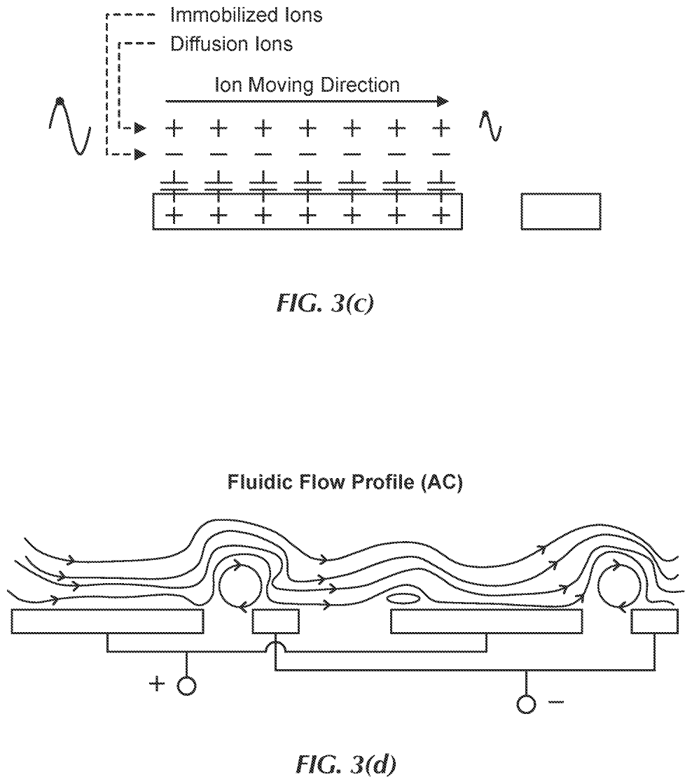

While the previous description provides a general guidance of nonlinear electro-osmotic flow, AC osmosis provides one possible mechanism to induce the electric fields, as shown by FIGS. 3(a)-(d). Electro-osmotic flow can be induced with a DC field. However, in this case, the required voltage in DC osmosis is directly proportional to the separation distance between the electrodes. This can reach to hundreds of volts when the channel length, and therefore, the separation electrodes extend beyond 100 μm. This makes such bulk fluid drivers non-scalable.

AC osmosis, on the other hand, relies on laterally positioned asymmetric electrode pairs, lowering the voltage requirements that is able to be handled by CMOS ICs. As shown in FIGS. 3(a)-(d), to ensure that the bulk fluid travels uni-directionally, AC electro-osmosis takes the advantage of the asymmetric nature of the electrode configuration to generate an AC tangential electric field profile that eventually contributes to bulk fluid motion.

Electrode Configuration and Bulk Fluid Flow

As shown in FIGS. 3(a)-(b), the interaction of the asymmetric electrodes with the electrolyte solution can be represented by an equivalent circuit model at the electrode-electrolyte interface. Here, C_{DL} represents the double layer capacitance and R₁ to R_{N} represent the bulk fluid resistance (R₁>R_{N}) for each current path. To calculate the tangential electric field to quantify the fluid flow, one can calculate the voltage difference between V_{N} and V₁, as shown in FIG. 3(a). Due to the voltage difference between V_{N} and V₁, this tangential field behaves with a standard second-order band-pass response, with the peak amplitude occurring at the center frequency ω₀:

$${V}_{t} = {V}_{N} - {V}_{1} = \frac{{jA}_{O} \frac{ω}{{ω}_{0} Q}}{1 + j \frac{ω}{{ω}_{0} Q} - {( \frac{ω}{{ω}_{0}} )}^{2}} {V}_{A C} \qquad ( 1 )$$

where Aₒ=C_{DL,S}(R_{N}−R₁)/(R₁+R_{N})(C_{DL,L}+C_{DL,S}), Q=\sqrt{R₁R_{N}}/(R₁+R_{N}) (C_{DL,L}+C_{DL,s}) (quality factor), and ω₀=(C_{DL,L}−C_{DL,s})/(C_{DL,S}C_{DL,L}\sqrt{R₁R_{N}}). In addition, the absolute voltage at V_{N} is larger than V₁, since R_{N}>R₁. This yields a net electric field pointing from the far edge of large electrode towards small electrode during positive AC cycle, as shown in FIG. 3(c). The diffusive positive ions are then dragged from the larger to the smaller electrode. When the cycle reverses, the direction of the field reverses as well the sign of the ions. This results in a unidirectional force exerting on the ions in the diffusion layer during all cycles, creating a fluid flow as shown in FIG. 3(d).

The velocity of ion (vᵢₒₙ) in the diffusion layer can be evaluated from the tangential electric field

$$( {E}_{t} = \frac{Δ V}{Δ L} = ( {V}_{N + 1} - {V}_{N} ) L )$$

(where ΔL is the separation distance between the two locations) as

$${v}_{i o n} = μ {E}_{t} = C \frac{ε ζ}{η} \times \frac{Δ V}{Δ L} \qquad ( 2 )$$

where μ is the ionic mobility, ∈ is the dielectric constant of the fluid, η is the fluid's dynamic viscosity, ζ is the zeta potential at the double layer (shown in FIGS. 2(a)-(b)), and C is a constant of value ⅔. In addition, zeta potential (ζ) represents the potential at the top plate of C_{DL} (shown in FIG. 3(b)), which results in vᵢₒₙ∝V_{AC}².

Given the nature of the electrolyte and ionic concentration, the configuration objective behind choosing the width and gap for the AC osmosis electrodes becomes clear: maximize conversion of electrical energy to kinetic energy of the fluid. This can be achieved by maximizing ΔV at the center frequency ω₀, as shown in Equation (1).

Cell Electronic Focusing, Sensing, and Separation

Precise control of the flow of cells is critical for high sensitivity cytometry. In prior works, hydrodynamic force has been mostly deployed to allow focusing of cell motion within a narrow streamline flow, thereby, enhancing overall specificity and sensitivity. This requires additional pneumatic-based microfluidic pumps.

An alternative way of manipulating cells in the microfluidic system is through dielectrophoresis (DEP). DEP relies on creating a net force on a suspended polarizable particle (such as cells) in a non-uniform electric field.

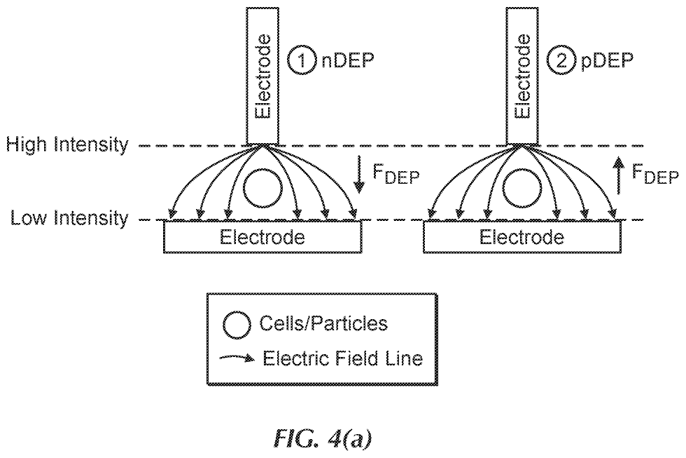

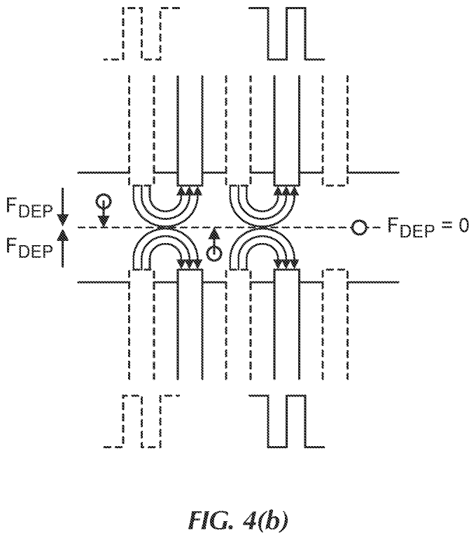

With the ability to precisely engineer the optimal fields with an array of electrodes controlled by custom configured CMOS circuits, the need for any hydrodynamic focusing can be eliminated and replaced with electronic focusing, cell manipulation, and sensing. The force exerting on a dielectric particle in a nonuniform field can be evaluated as:

$${F}_{D E P} = 〈 ( P \cdot ∇ ) E 〉 = \frac{3 π}{2} {ϵ}_{m} V \cdot Re ( {f}_{c m} ) ∇ {\vert {E}_{r m s} \vert}^{2} \qquad ( 3 )$$

where P=pV is the induced dipole under an external electric field, V is the volume of the particle, Eᵣₘₛ is the root-mean square (RMS) intensity of the electrical field, and f_{cm} is the Clausius-Mossotti factor which quantifies the dipole moment of the particle relative to the solution medium. This factor can be quantified as follows:

$${f}_{c m} = \frac{{∈}_{p} - {∈}_{m}}{{∈}_{p} + 2 {∈}_{m}} \qquad ( 4 )$$

where ∈ₚ and ∈ₘ represents the complex permittivity of the particle and the fluid medium. Therefore, with an array of electrodes with independent drive capability, one can engineer the nature of the electric fields within the channel, creating precise positioning of the cells, which allow for high precision cytometry and subsequent separation capabilities, as shown by FIG. 4(b).

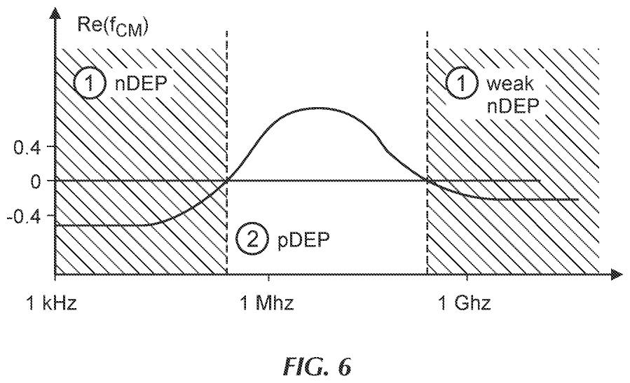

Given that both ∈ₚ and ∈ₘ depend on frequency, the direction of the DEP forces can change depending on the frequency of operation, offering another degree of freedom to manipulate cells. For example, when a red blood cell (RBC) is present in isotonic buffer of 8.5% sucrose+0.3% dextrose (≈60 mS/m⁻¹), the inversion of DEP force occurs at around 1 MHz, as shown by FIG. 6. At low frequencies, f_{cm}<0, and negative DEP (nDEP), forces exert on the cell pushing it towards the direction of lower electric field intensity, as shown by FIG. 4(a). Beyond the first crossing point, f_{cm}>0, and the force reverses its direction. At very high frequencies close to GHz, f_{CM} turns negative again, but the force magnitude is much smaller compared to the first nDEP region. Here, a stronger nDEP operating in the range of hundreds of kHz is chosen, though that is not intended to be limiting.

For DEP to operate effectively, the required electric field intensity is reported to be on the order of 10⁵-10⁶ V/m. This indicates that under 5V of voltage excitation, the separation of the DEP electrode within the microfluidic channel is around 50 μm.

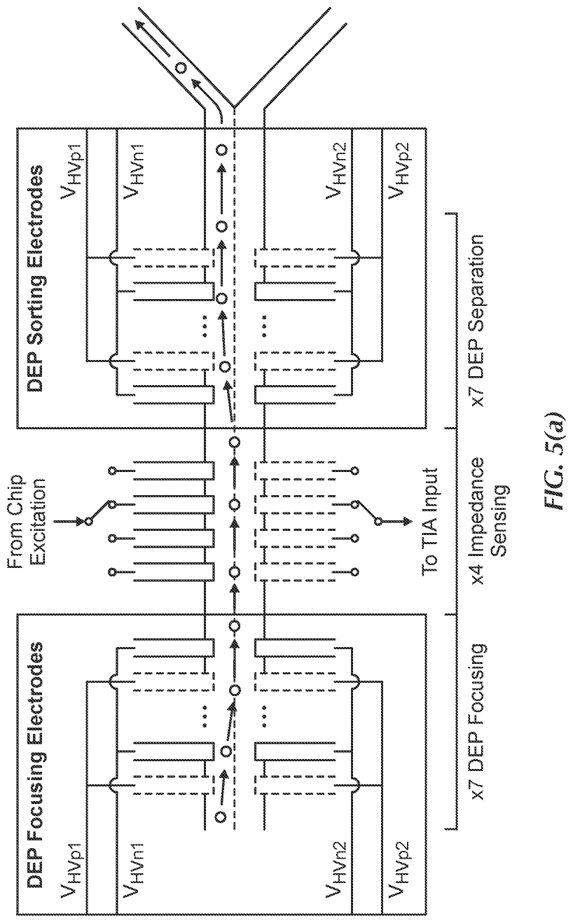

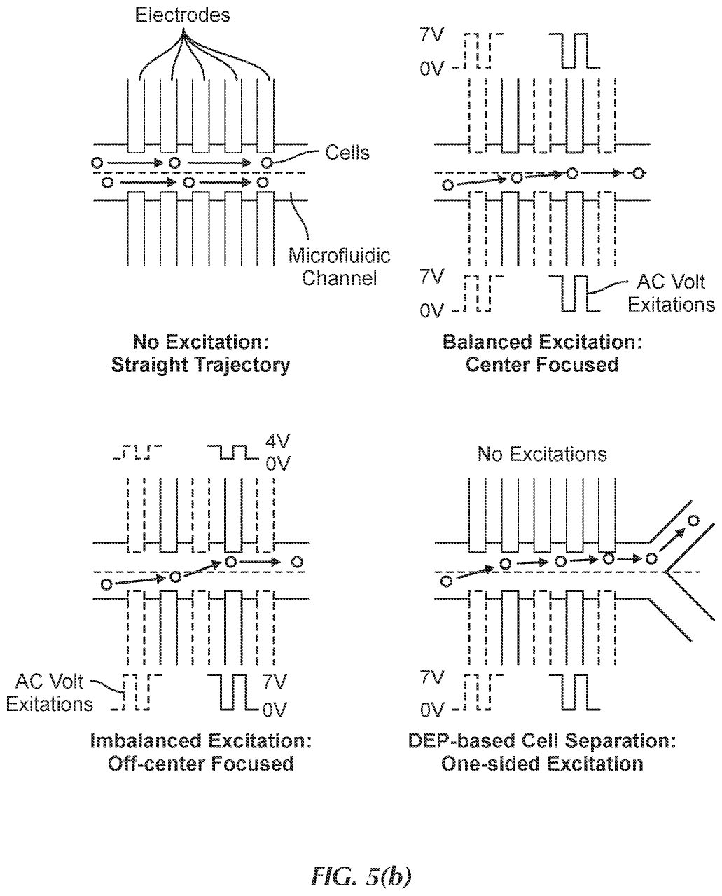

With the aforementioned functionalities, disclosed herein is a system of electrodes capable of performing cytometry, cell actuation, and AC osmosis driver on a single glass substrate. As shown in FIG. 5(a), a series of vertical gold electrodes are aligned in the microfluidic channel. Gold electrodes are fabricated here to reduce the chemical reactions between the electrodes and ionic solution, due to its non-active chemical nature. The first seven pairs of electrodes are dedicated to cell focusing, where electric field within the channel can be synthesized on the fly by controlling the difference of the AC voltage magnitudes on either side of the channel. The frequency here is chosen below 500 kHz such that the cells only experience strong nDEP force; however, that frequency is not intended to be limiting.

As shown in FIG. 5(b), when the electrodes are not excited, the cells will pass along the channel with randomly distributed lateral positions. In the case of balanced voltage excitations, the gradient of the electric field will be minimized in the center of the channel. Therefore, the cells will be center-focused. In the case of imbalanced excitation, the minimum gradient will be pushed towards the side with smaller voltage excitation, resulting in an imbalanced cell focusing. In an extreme case, where only one side of the electrodes are activated, cells will be completely pushed towards one side of the channel. In this case, the configuration can be used to separate the cells into different diverging channels, indicated by the last seven pairs of electrodes.

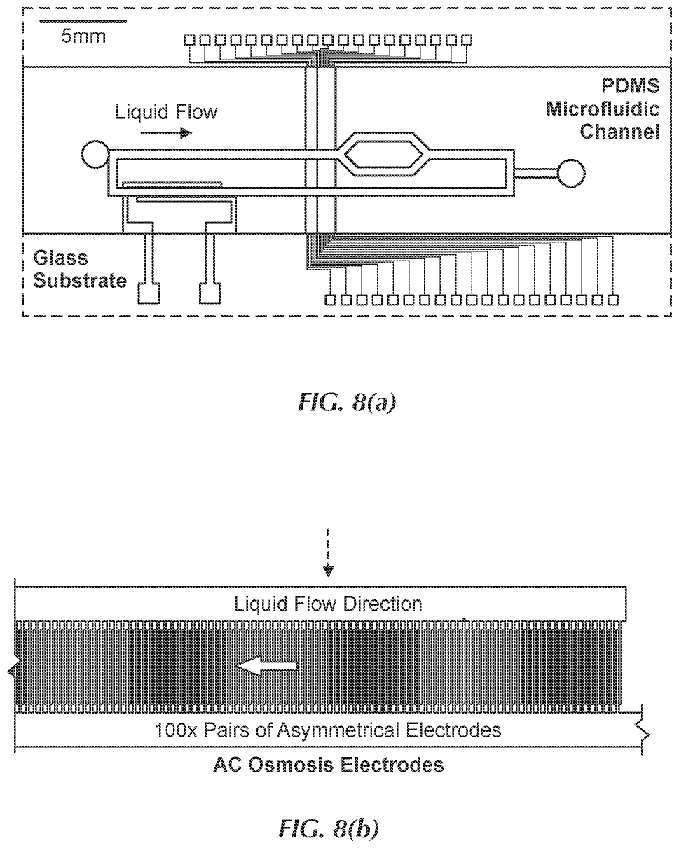

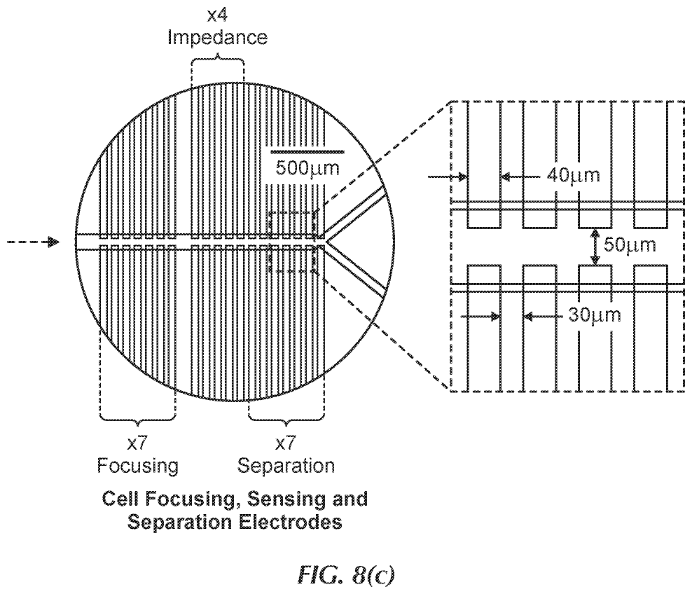

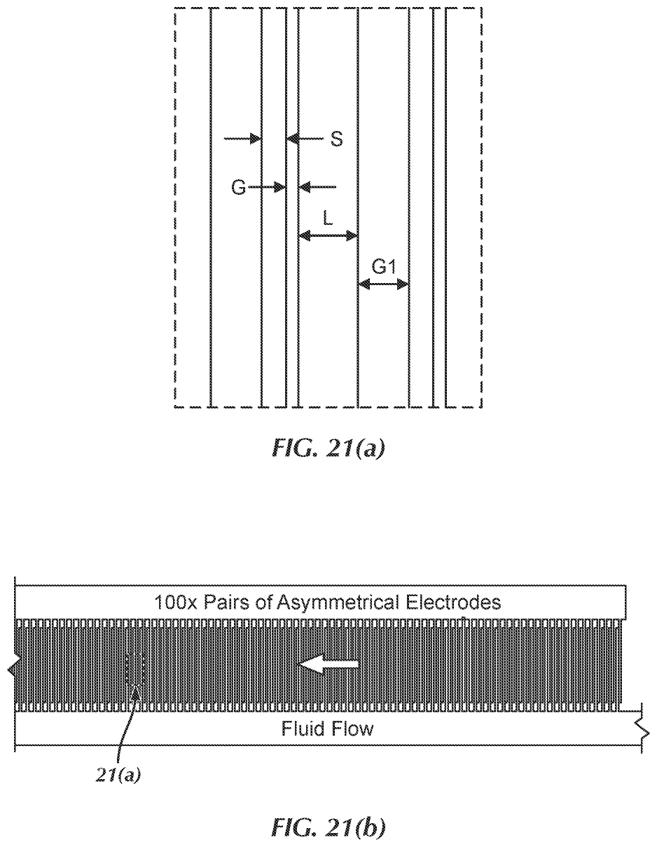

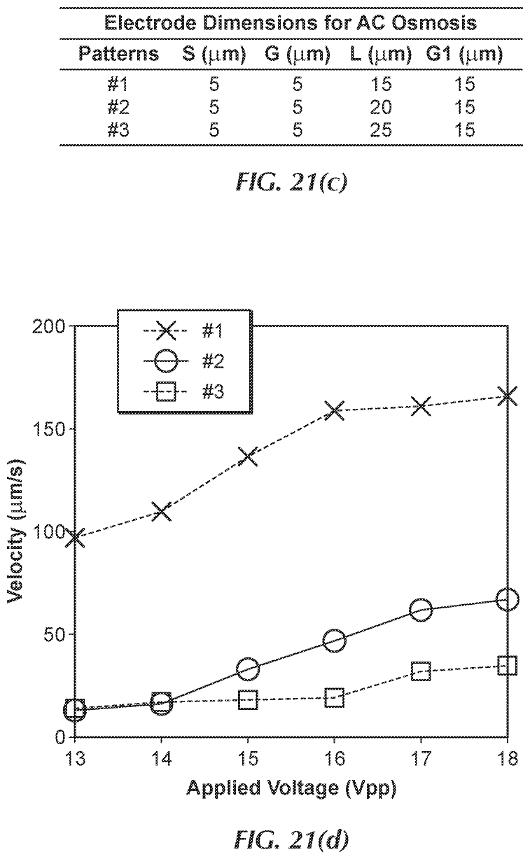

In between the cell focusing and separation electrodes, are four pairs of impedance sensing electrodes that are able to capture cell flow in microfluidic channel in real-time. The top four electrodes are designated for voltage excitation, where the bottom four are directly connected to the receiver inputs. To simplify the configuration, all of the DEP and impedance sensing electrodes have a width of 40 μm and separation of 30 μm, as shown later in FIG. 8(c). The proposed electrode dimensions can be optimized for different cells sizes; therefore, the system functionality should not be constrained to these numbers. In addition, the electrode dimensions for AC osmosis are shown in FIG. 21(a) on the same glass substrate.

Impedance Spectroscopy Sensing

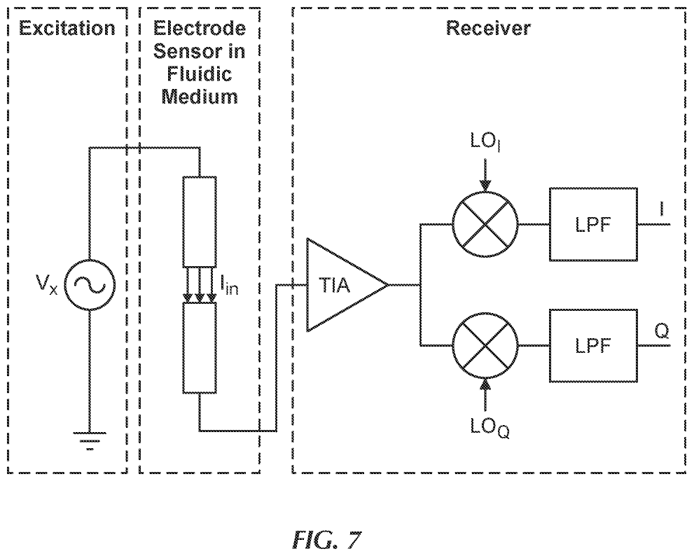

Built on top of the AC electro-osmosis bulk fluid driver and DEP cell actuation, is a 16-array impedance spectroscopy receiver based on a direct conversion architecture. The purpose of the impedance spectroscopy sensing is to provide the impedance measurements in real-time at the electrode-electrolyte interface. This sensing modality is employed for cytometry sensing, and for label-free protein bio-assay in this multi-modal bio-sensing platform. As shown in FIG. 7, the impedance-spectroscopy sensing system constitutes a low-noise transceiver system, including voltage excitation driver, transimpedance amplifier (TIA), in-phase (I) and quadrature (Q) mixer as well as low-pass filter (LPF).

The voltage source, Vₓ, shown in FIG. 7, excites the sample at a frequency that is optimized for extracting the highest response from the sample. The changing event (such as protein-protein binding or cell passing) creates a transient change in the dielectric constant locally, resulting in a deviation of input current signal (Iᵢₙ=A_{I}·sin(ωt+ϕ)), amplitude (A_{I}), and phase (ϕ). The TIA converts the input current to voltage with a transimpedance gain of A and detects the amplitude and phase change to infer about the biosensing event. Sensitivity for immunoassays can be maximized by operating frequencies around 500 kHz-1 MHz. Here, the primary focus is on probing both cytometry and immunoassays around f₀=500 kHz, though that is not intended to be limiting.

Bio-Molecular Sensing

Bio-molecular sensing, compared to cell sensing, focuses on detecting a bio-molecular binding event, such as protein-protein interactions and complementary nucleic-acid binding activities. In labelled detection, extra labelling molecules or particles (such as fluorophores or magnetic beads) are relied on to produce a signal which is then detected by a transducer. However, for label-free detection, the bio-molecular binding event is detected directly through methods such as but not limited to impedance spectroscopy and optical resonance. Here, impedance spectroscopy is deployed, as it can be realized through compact CMOS technology without any external instrumentations and is compatible with compact POC diagnostic applications.

The sensor electrodes are first activated with probe molecules that will only bind with specific target molecules. Therefore, when a bio-molecular binding event occurs on the electrode surface, it causes a tiny impedance change which can be detected by the on-chip current sensor, resulting in a positive signal. The on-chip impedance spectroscopy, in general, can be adapted to any bio-molecular detection in a compact form, where the probe molecule can be customized to any bio-molecular sensing application, such as protein antibodies in immunoassay or nucleic-acid sequence probes for viral DNA/RNA detection in a sample.

Microfluidic Device Fabrication and Assembly

The microfluidic flow assembly is shown in FIG. 8. The sample through the inlet is driven by a set of AC-osmotic electrodes controlled by the chip. The sample then passes through the described set of electrodes for cell focusing, sensing, and separation. The processed fluid can be further investigated for protein sensing, to be described further below.

Electrode Fabrication

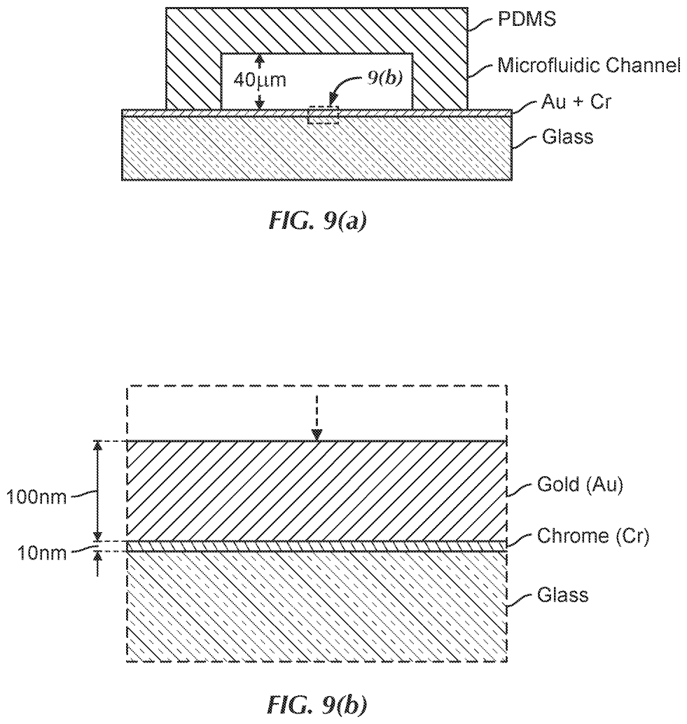

Here, borosilicate float glass is used as substrate, as a nonlimiting example. A silicon wafer can also be used as a substrate, glass is known to best bind with PDMS. The electrode pattern can be fabricated through any standard photolithography procedure. First, a 10 nm layer of Chrome (Cr) is deposited as an adhesive layer, followed by a 100 nm of gold (Au) layer deposition. Other adhesive metals such as but not limited to tungsten, niobium, and titanium can be used in alternative embodiments. Au is chosen as the interface between the electrode-electrolyte interface, to take advantage of its inert chemical nature with ionic liquid. The deposition can be conducted with an e-beam evaporator. Next, the metal layer was removed with photoresist, and the electrodes were formed by a lift-off process. The resulting glass-metal interface is demonstrated at the bottom of FIG. 9.

Microfluidic Channel Fabrication and Assembly

Polydimethylsiloxane (PDMS) microfluidic channels can be fabricated through soft photolithography. Glass or SU-8 can also be used as the material for the microfluidic channel in alternative embodiments, as nonlimiting examples. Initially, a SU-8 2025 layer is spin-coated at 3000 rpm on a silicon wafer and soft-baked at 65° C. for 1 min and 95° C. for 6 min. The wafer is then exposed to UV and is post-exposure baked at 95° C. for 6 min. After that, the wafer is developed using a SU-8 developer, followed by a wash with isopropanol and drying. The mold wafer was then used for PDMS casting with curing temperature set to 80° C. for one hour. Finally, the PDMS was peeled off and punched with 1.5 mm-diameter holes for fluid inlets and outlets.

Here, the microfluidic channel has a height of 50 μm and is aligned over the gold electrode device using a custom aligner that includes 3-axis micromanipulators and a microscope. Finally, the PDMS channels are covalently bonded to the glass substrate using UV/O3 cleaner for 20 min. The device is then incubated at 95° C. for 20 min on a hot plate to increase the bonding strength. Finally, the complete channel-electrode interface is shown at the top of FIG. 9.

It should be noted that the fabrication method described herein is based on the prototype developed (glass wafer electrodes and PDMS microfluidic channel) and not intended to be limiting. For instance, the fabrication method will differ based on different materials such as SU-8 or glass-based microfluidic channels, and is generally understood by those skilled in the art. The electronic interface should work with most fabricated sensors as long as there are electrodes extending out from the substrate.

Circuits and System Implementation

This section describes an on-chip architecture for controlling AC-osmotic flow, cell flow, and sensing with integrated impedance spectroscopy. The chip is configured and fabricated in a 65-nm LP bulk CMOS process. This particular process is chosen to optimize the performance at low power operation for POC applications but is not intended to be limiting. Other process nodes can be used as well to achieve the same functionality.

AC-Osmosis and DEP Driver Architecture

To provide a driving signal for both the AC electro-osmosis and DEP electrodes, the system includes a programmable signal generator. On-chip high voltage drivers are employed for the DEP system (>5 Vpp). The signal is further boosted with off-chip drivers for swings higher than 10 Vpp for AC osmosis. While the boosting was achieved off-chip for AC-osmosis in this exemplary chip, this can be easily integrated in a longer node CMOS process with higher breakdown voltage limits.

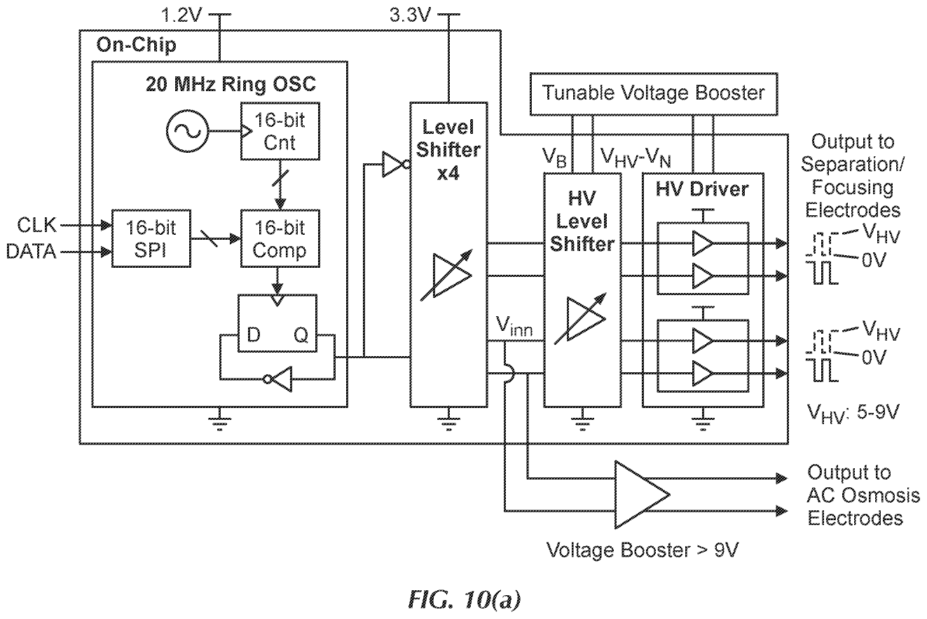

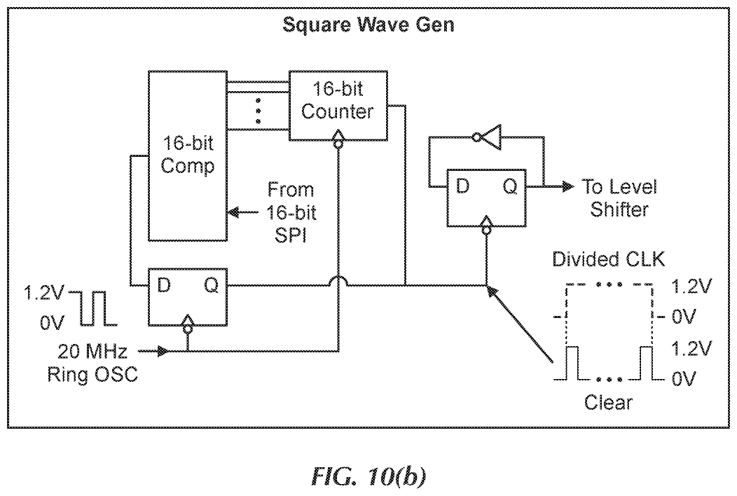

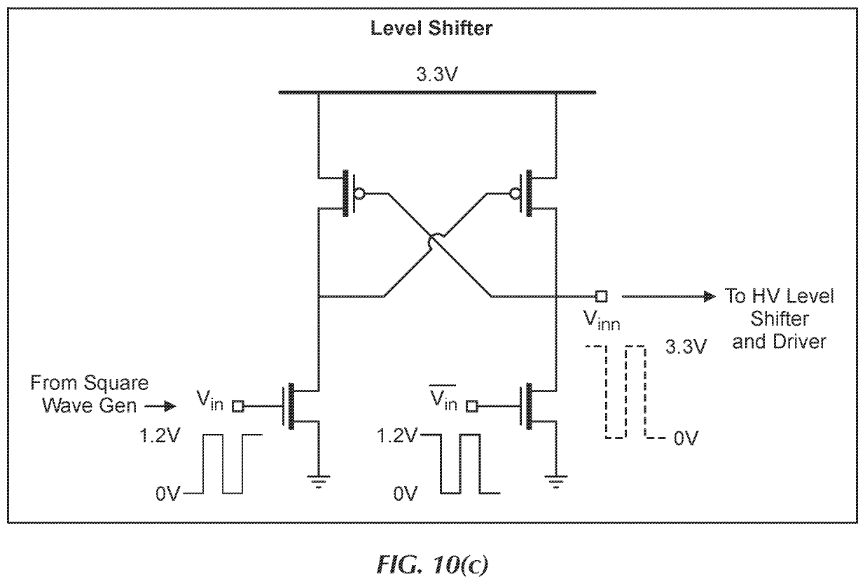

FIGS. 10(a)-(c) show the circuit architecture for the high-voltage square wave generator. It includes three major components: a programmable square wave generator operating at 1.2V with serial peripheral interface (SPI), a 3.3V digital level-shifter, and high-voltage level-shifter and driver for DEP electrodes.

Programmable Square Wave Function Generator:

The core of the square wave function generator includes a 20 MHz three-stage ring oscillator and a 16-bit synchronous counter. The 16-bit counter can be periodically reset through the comparators, where the resetting time can be digitally controlled through a SPI interface, as shown in FIG. 10(b). With this approach, the square wave generator block is capable of providing driving frequencies from 300 Hz to 10 MHz that is sufficient to cover the operations of both AC osmosis and DEP.

High-Voltage Level Shifter and Driver:

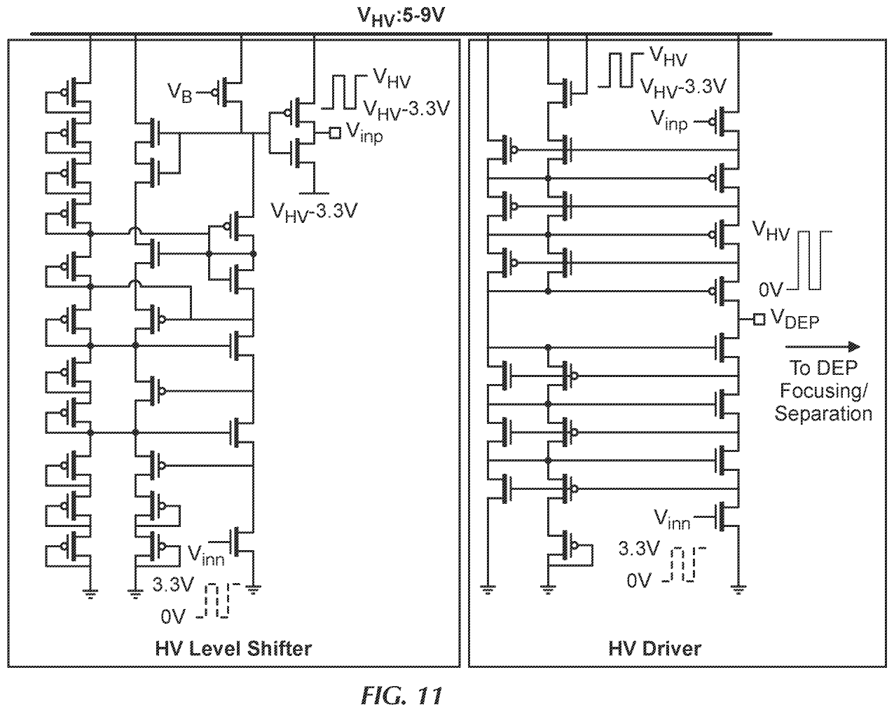

The output of the 1.2V square wave is first level shifted to a 3.3V reference (realized with thick-oxide devices), as shown in FIG. 10(c). This signal is then sent to the on-chip high-voltage (HV) level-shifter and driver to generate the DEP signal, as shown in FIG. 11, or sent off chip to generate the AC electro-osmotic drive signals.

The HV level-shifter, in particular, uses a stacked topology with thick oxide transistors and with self-biasing circuitry to simplify the overall design and complexity, as shown in FIG. 11. It is ensured that the node voltages are kept within the safe limits, and the maximum swing is set by the p-n junction breakdown voltage (9 V) of the source/drain and substrate region.

As shown in FIG. 11, the HV level shifter converts a 3.3V square wave (Vᵢₙₙ) to level-shifted 3.3V square wave (Vᵢₙₚ) for the HV driver. The circuit is realized through three vertical branches of stacked transistors. V_{HV} is set through a boost converter and can be tuned from 5-9V to cover a sufficient supply voltage for DEP electrodes. The biasing current, controlled through V_{B}, is set such that when Vᵢₙₙ is low, the top PMOS has the capability to pull up the gate of voltage of inverter stage. Therefore, Vᵢₙₚ can be pulled down to V_{HV}−3.3V.

Next, both Vᵢₙₚ and Vᵢₙₙ are fed into the HV driving stage together, which also includes three vertical branches of stacked transistors. The first two vertical branches of stacked transistors on the left of the HV driver are necessary to provide proper biasing voltages for the stacked transistors at the output (V_{DEP}).

In summary, the output of the HV driver is capable of providing square wave driving signal between 5-9V. Two HV drivers generate a differential signal pair that drives the DEP focusing and separation electrodes, that is sufficient to cover the minimum electric field intensity (10⁵ V/m) required for DEP electrodes with 50 μm of separation.

Impedance Spectroscopy Receiver Architecture

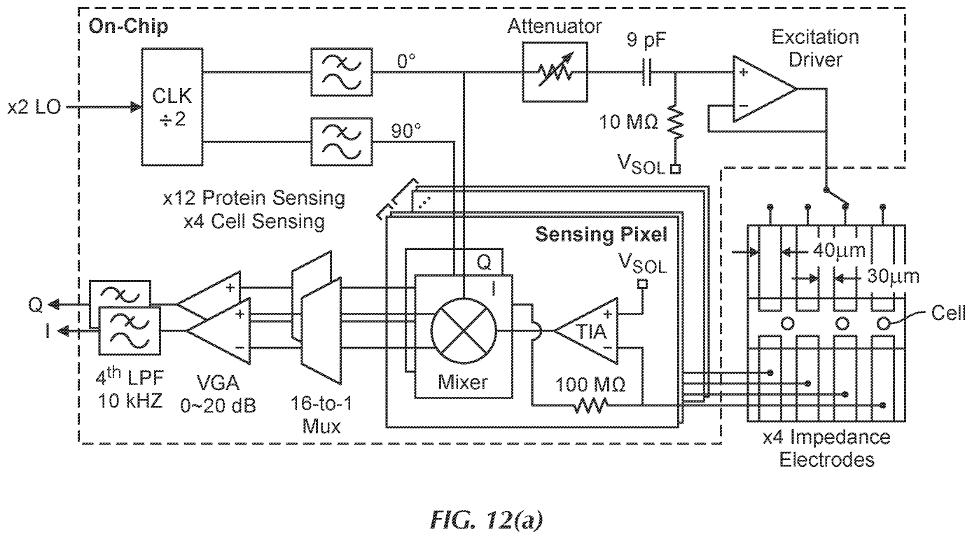

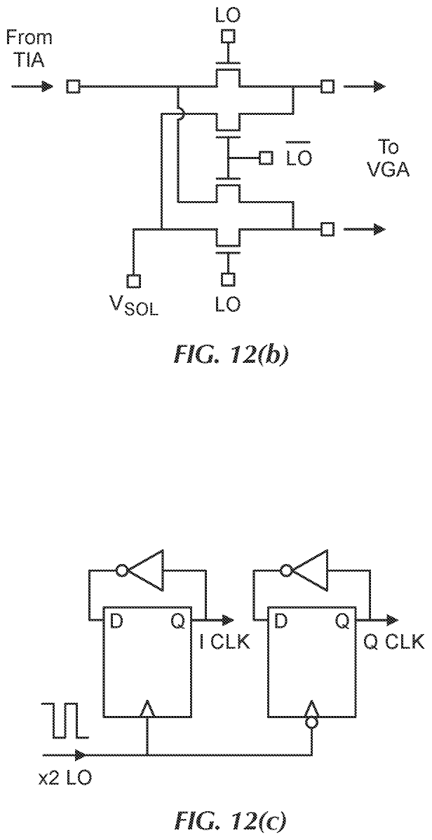

The purpose of the direct conversion receiver, as aforementioned, is to provide real-time impedance sensing for the cytometry in the microfluidic channel and for protein sensing, as shown in FIGS. 12(a)-(c).

Excitation Path:

The excitation signal is generated internally through the divide-by-2 I/Q clock generator, shown in FIG. 12(c). It is implemented through two flip-flops capable of providing both the in-phase and quadrature-phase waveforms. The in-phase signal then has the option to be low-pass filtered to remove the higher order harmonic from the square wave and then fed to a programmable attenuator (realized through resistor divider).

The signal is then high pass filtered through a combination of on-chip metal-oxide-metal (MOM) capacitor (9 pF) and resistor (10 MΩ poly resistor) to pin the output DC voltage to V_{SOL}, as shown in FIG. 12(a). The configuration of the excitation driver is based on a standard two-stage op-amp with capacitive miller compensation. The op-amp driver is configured with a bandwidth of 10 MHz capable of penetrating the double-layer capacitance (C_{DL}) at the electrode-electrolyte interface.

Trans-Impedance Amplifier (TIA):

An op-amp based TIA is employed with a R_{FB} of 100 kΩ in feedback to achieve a bandwidth of 2 MHz. The op-amp topology employed in the TIA is similar to the driver op-amp in the excitation path. However, in this configuration, the length of the input differential pair is significantly increased to 1 μm to minimize the 1/f noise. Since the subsequent passive mixer translates the noise spectrum, the output voltage noise of the receiver path has a significant contribution from the VGA and LPF due to the low signal bandwidth (10 kHz) and presence of 1/f noise of the later stages.

Passive Mixer, Differential-To-Single-Ended VGA and LPF:

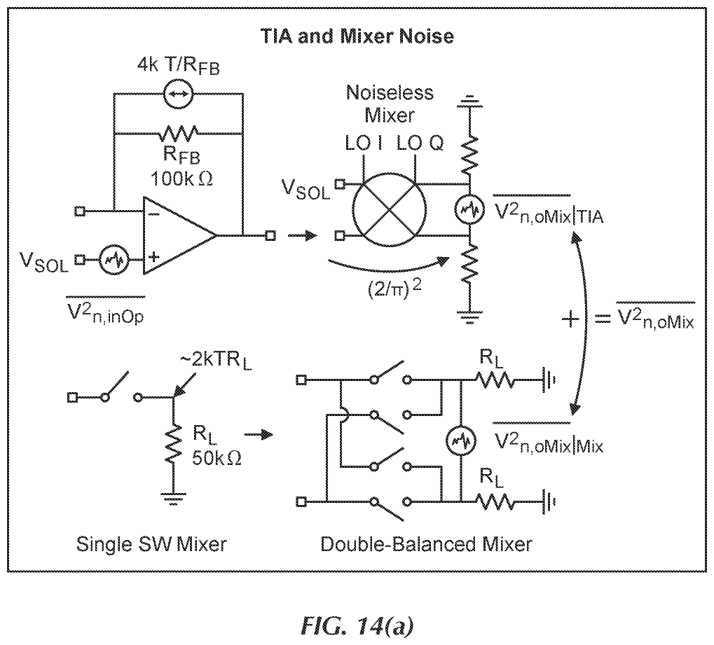

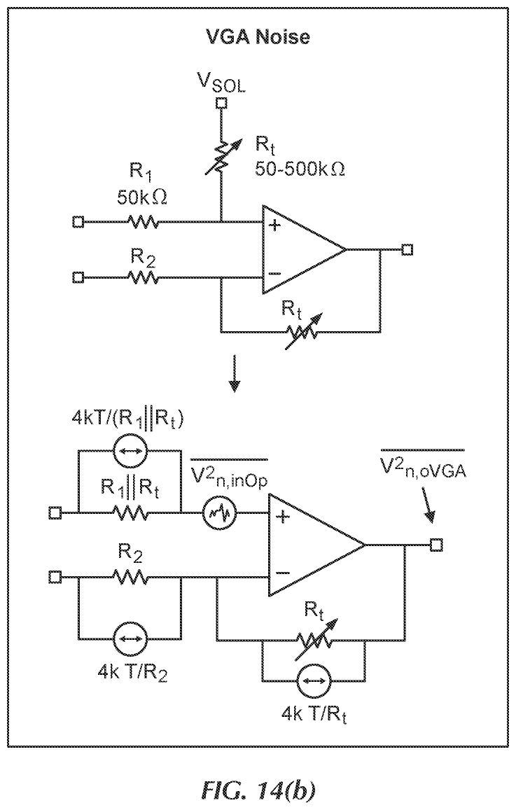

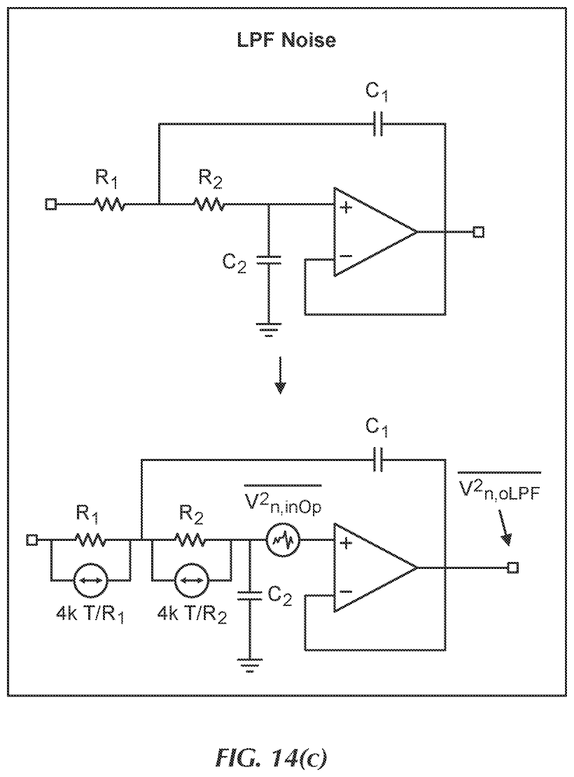

A double-balanced passive mixer is used to minimize power consumption, LO feed-through, and maximize the conversion gain, as shown in FIG. 12(b). To further increase the sensitivity of the receiver, an additional programmable is used VGA with a digitally tunable gain ranging from 0-20 dB, shown in FIG. 14(b). After the programmable VGA, a LPF is employed to filter higher order harmonics. The LPF is configured with a 4th order Butterworth response by cascading two second order Sallen-Key LPF in series, shown in FIG. 14(c). Together, the overall LPF is capable of achieving a 10 kHz filtering bandwidth with 80 dB/dec roll-off beyond the 10 kHz cutoff frequency.

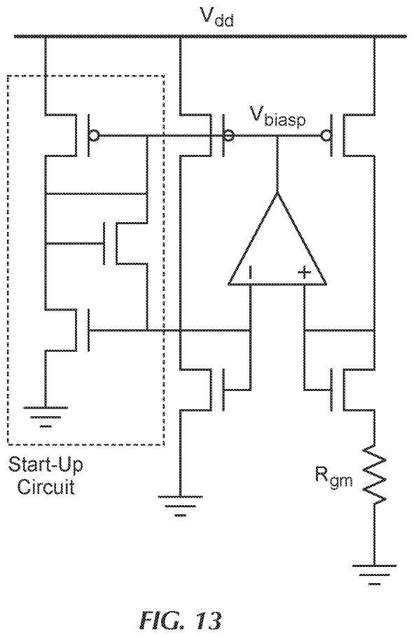

To bias all the analog components, the chip deploys a constant-gm self-biasing circuit in order to minimize the usage of external biasing pads. As shown in FIG. 13, due to the short channel nature of 65-nm LP process, the constant-gm biasing core is configured with an additional differential-to-single-ended amplifier to clamp the V_{biasp} across a wide range of supply voltage. In addition, a start-up circuit is configured to provide a discharging path in order to avoid V_{biasp} being latched to V_{dd}. With this approach, the constant-gm self-biasing circuit is able to achieve a consistent 20 μA across a wide range of supply voltages between 1.2 and 2.5V.

System Noise Analysis

The noise of the system is primarily contributed by a combination of the input TIA, mixers, VGA, and the low pass filters, as shown in FIGS. 14(a)-(c). A major challenge in the configuration of the impedance spectroscopy receiver is that the spectrum of the desired signals (such as for cytometry), is located in the frequencies below 10 kHz. This is primarily determined by the dynamics of the bio-sensing interface such as the flow velocity of the cells that move across the electrodes array.

As an example, for an AC osmotic flow rate of 100 μm/s (to be illustrated in the measurement section), the time taken for a cell to pass through one sensing electrode of width 40 μm is ˜0.25 s. To capture this dynamic with high sample rate (to identify and classify different cells, if needed), the integration time is kept below 0.1 ms, or in effect, the integration is set around 10 kHz by the LPF. Therefore, the 1/f noise of the circuitry after the frequency translation of the mixer becomes critical.

TIA and Mixer Noise:

The output noise of the TIA around the frequency of analysis (f₀≈500 kHz) gets translated down to the signal frequency at baseband after mixing. As show in FIG. 14(a), the output voltage noise spectrum of the TIA can be calculated as:

V̅_̅{̅n̅,̅o̅p̅T̅I̅A̅}̅²̅=4kTR_{FB}+V̅_̅{̅n̅,̅ι̅n̅O̅p̅}̅²̅ (5)

where V̅_̅{̅n̅,̅ι̅n̅O̅p̅}̅²̅ represents input voltage noise of the op-amp used in the TIA. After frequency translation through the differential passive mixer with an average fundamental frequency voltage gain of 2/π, the receiver output noise spectrum due to TIA alone has a spot noise of 0.18 pV²/Hz. When integrated over the 10 kHz LPF bandwidth, the TIA noise contribution at the receiver output yields around 42 μV of RMS noise voltage.

In addition, assuming fast switching with 50% duty cycle in the double-balanced passive mixer, the output noise spectrum contributed by the mixer itself, can be approximated as 8kTR_{L}, where R_{L} is the equivalent output loading resistance of the mixer. Combining TIA noise, the net spot noise at the output of the receiver, due to the TIA and the mixer circuits can be evaluated to be 0.32 pV²/Hz. Within the LPF bandwidth of 10 kHz, the total noise contribution due to TIA and mixer combined can be calculated to be ≈57 μV of RMS noise voltage.

Programmable VGA and LPF Noise:

As mentioned before, the 1/f noise portion in VGA is critical in the total noise contributions. Shown in FIG. 14(b) are the noise contributors. The noise voltage at the input of the VGA due to R₁∥Rₜ and R₂∥Rₜ can be evaluated as 4kT(R₁∥Rₜ+R₂∥Rₜ). The total 1/f and white noise due to the op-amp can be represented as the input-referred noise (V̅_̅{̅n̅,̅ι̅n̅O̅p̅}̅²̅). Therefore, the total noise at the output of the programmable V̅_̅{̅n̅,̅o̅V̅G̅A̅}̅²̅ due to the contributions in FIG. 14(b) can be represented as:

V̅_̅{̅n̅,̅o̅V̅G̅A̅}̅²̅=A_{VGA}²(4kT(R₁∥Rₜ)+4kT(R₂∥Rₜ)+V̅_̅{̅n̅,̅ι̅n̅O̅p̅}̅²̅) (6)

where A_{VGA} is the gain of VGA and it is set to 20 dB. The input-referred noise spectrum density (V̅_̅{̅n̅,̅ι̅n̅O̅p̅}̅²̅) is simulated to be (0.19nV²/Hz)/f+(0.16fV²/Hz). The receiver output noise spectrum due to VGA, under maximum gain of 20 dB, can be evaluated to contribute a net noise of ≈415 μVrms within the 10 kHz of LPF bandwidth.

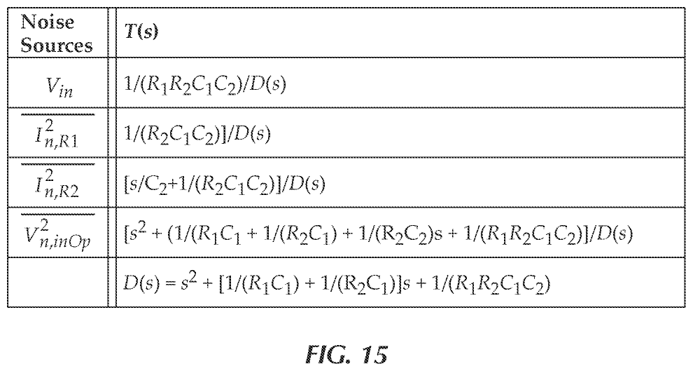

The receiver output noise due to the active 4th order LPF (V_{n,oLPF}²) can be evaluated by considering the transfer functions from each noise source within LPF to the output node, as demonstrated in FIG. 14(c). The table in FIG. 15 summarizes the small signal transfer function from each noise source to the output of the 2nd order LPF, and the output noise due to LPF alone is ≈117 μVrms.

Analysis of the noise sources show that the dominant noise source in the receiver chain, as predicted, arises from the 1/f noise in the VGA. The signal acquisition path for both cell and protein sensing is co-configured with the electrode and the receiver configuration, resulting in measured SNR of 10 dB and higher for cell sensing measurements, to be described further below. While these metrics can be further optimized, the achievable levels of sensitivity will allow for demonstrating the principles of multi-modal functionalities of the presented platform.

Measurement Results

This section presents the overall packaging, electrical performance, CMOS-driven AC-osmotic flow, cell manipulation, and bio-sensor measurements according to an embodiment of the invention.

CMOS Packaging and PCB System Implementation

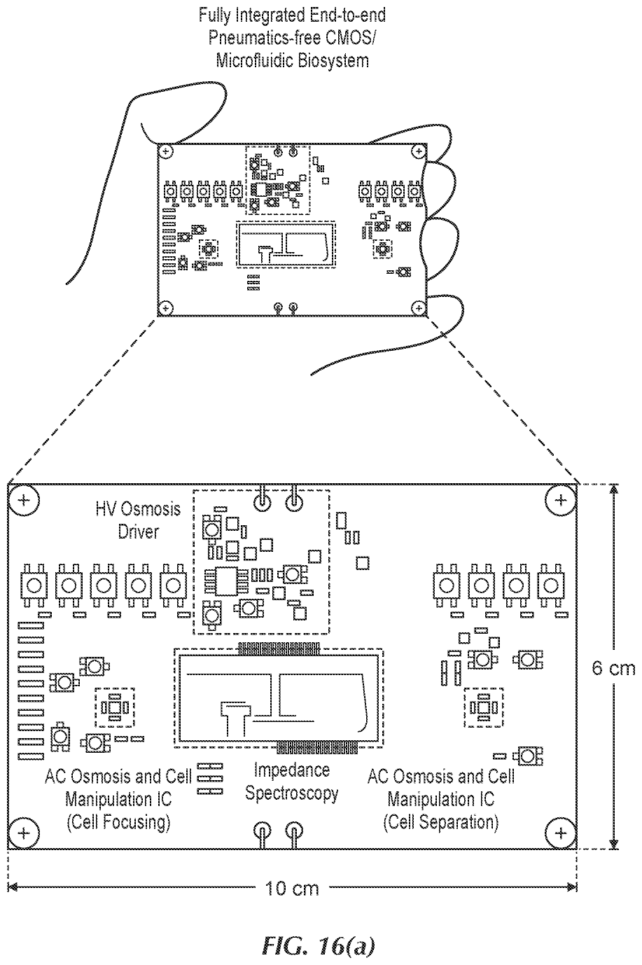

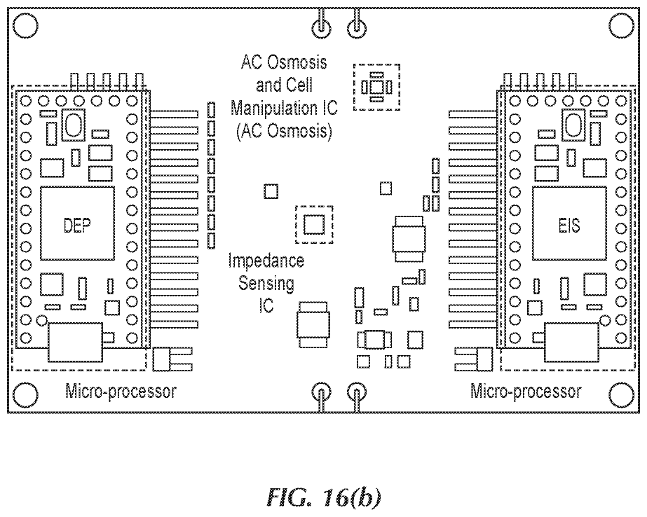

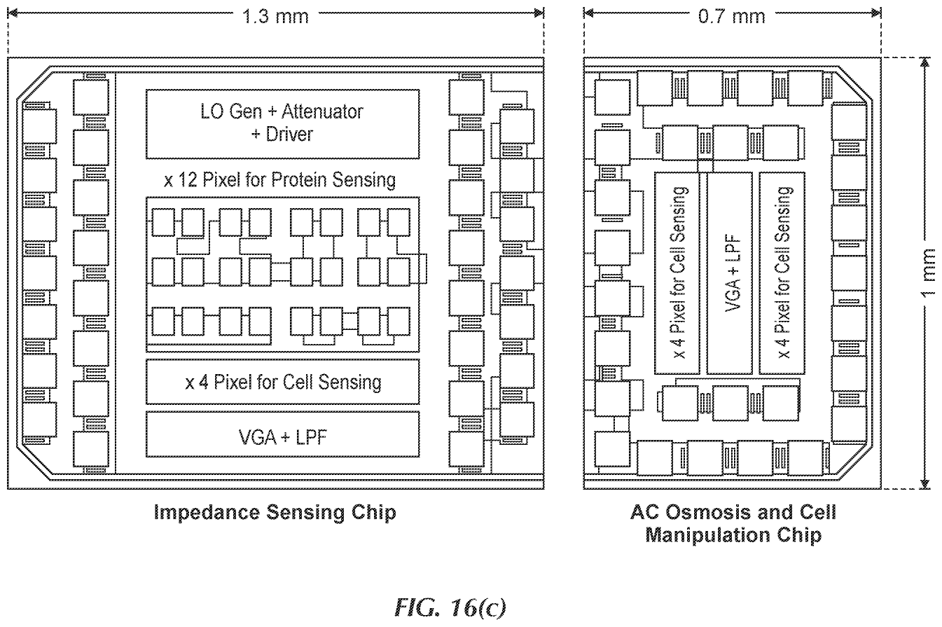

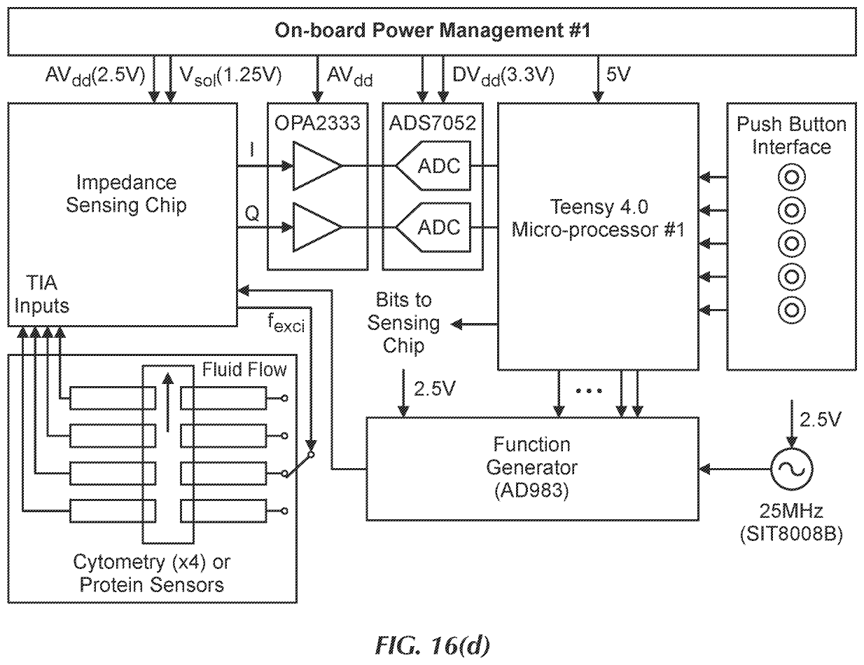

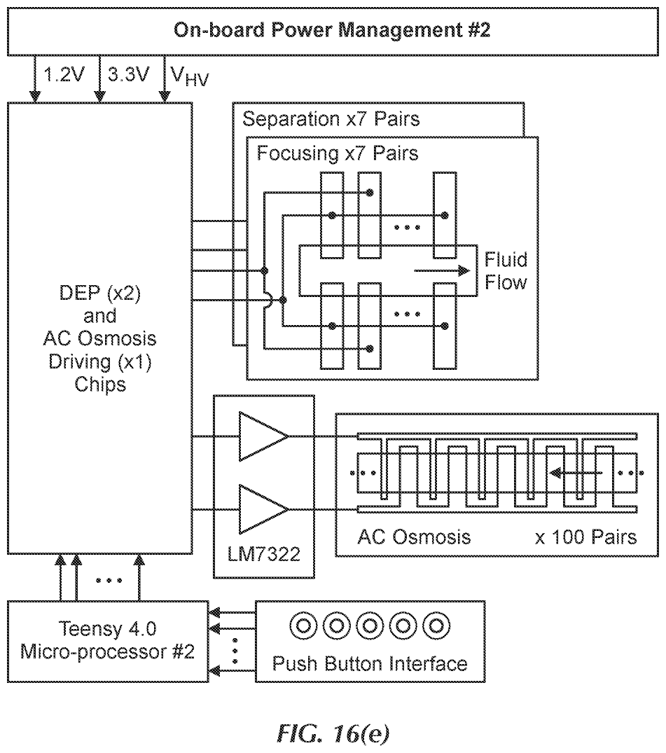

The overall system is shown in FIG. 16(a)-(e). The custom configured ASIC is fabricated in a 65-nm LP process. The chip is shown in FIG. 16(c). As the figures show, the DEP/AC osmosis chips are mounted both on the front and backsides of the PCB, and the impedance sensing chip is mounted at the back, as shown in FIGS. 16(a)-(b). All the chip I/Os and the passive microfluidic electrodes are wire-bonded to PCB. In addition, there are also peripheral surface mount circuitries that control, monitor, and process the signals into and out from the custom ASIC.

The bio-sensing platform can be powered by two sets of AA batteries. FIGS. 16(d)-(e) demonstrate the system configuration that are laid out to minimize crosstalk between the DEP/AC osmosis drivers, and the impedance spectroscopy receivers.

Electrical Characterization of Impedance Sensing Chip

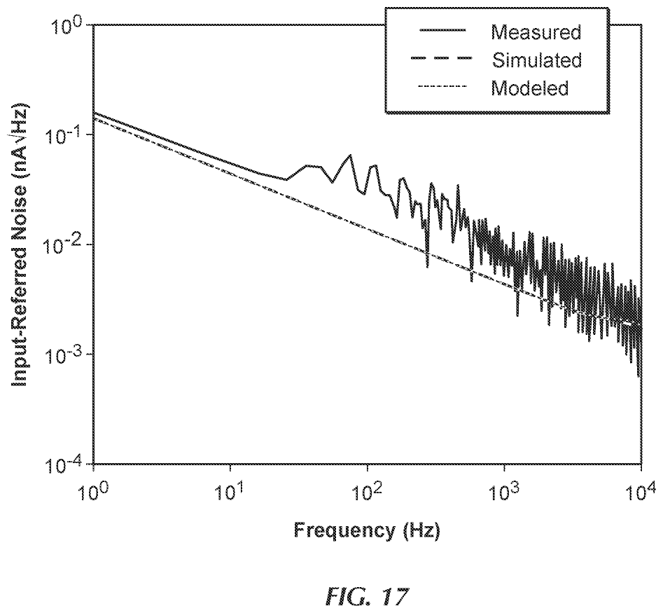

To characterize the sensitivity of the receiver, the receiver output is connected to an off-chip low-noise pre-amplifier (for example, Stanford SR560) and subsequently to a spectrum analyzer (for example, R&S FSW) to acquire the output noise voltage spectrum. The measured input-referred current noise is illustrated in FIG. 17. At a bandwidth of 10 Hz, 100 Hz, and 1 kHz, the input-referred current noise is measured to be 301, 536, and 812 pA RMS, respectively.

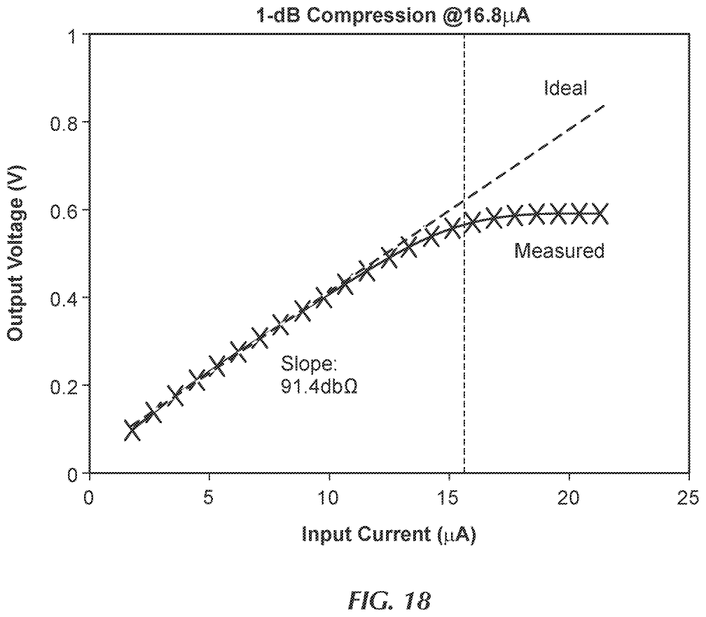

To measure the linearity of the receiver, a 10 kΩ resistor is connected between the excitation path and the TIA input. The VGA is set to unity gain for maximum linearity. As shown in FIG. 18, the 1-dB compression is measured for an input current of 16.8 μA. Combined with the input referred noise of 301 pA RMS at a bandwidth of 10 Hz, the impedance sensing system is capable of achieving a total dynamic range of 95 dB.

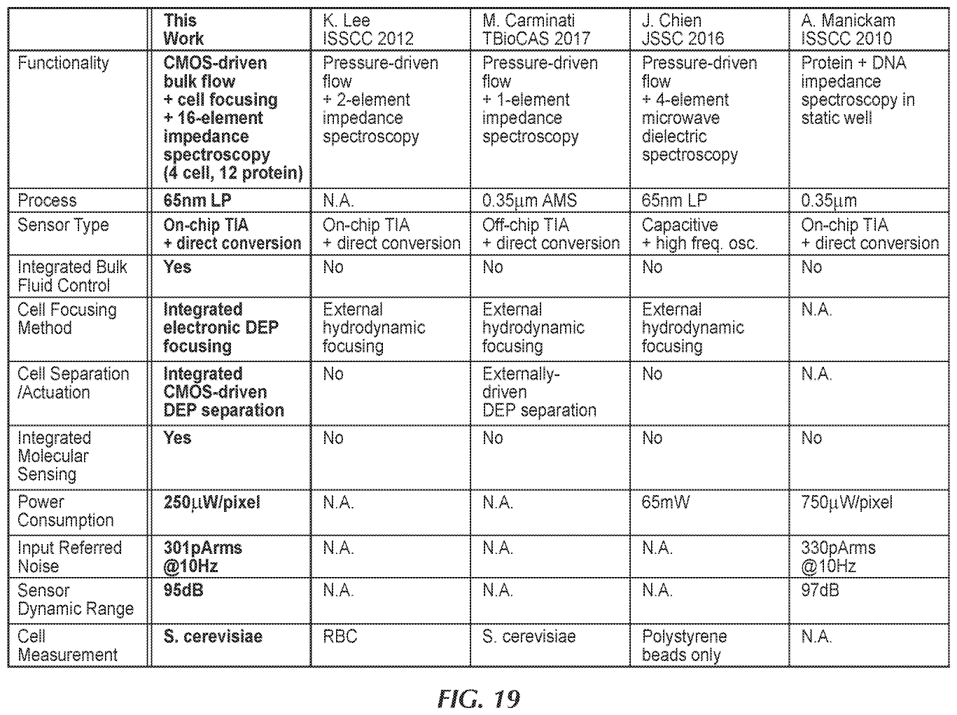

In summary, the input-referred noise and linearity performance is compared against other state-of-the-art CMOS impedance biosensors in the table in FIG. 19, providing sufficient sensing capability for both cell cytometry and protein essay.

DEP and AC Osmosis Driving Signals

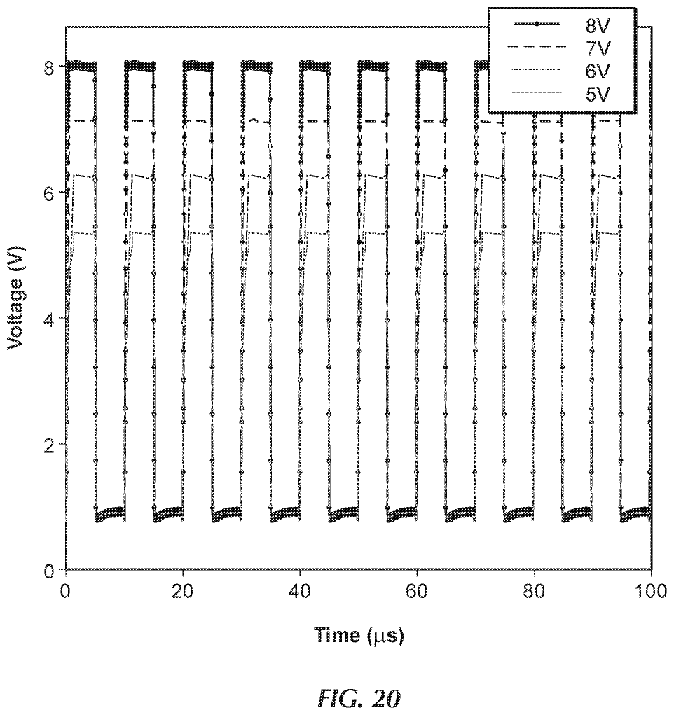

To test the high voltage driving capabilities across frequency, a 16-bit code is sent to the chip that sets the output frequency. FIG. 20 demonstrates a measured driving waveform at the output of the HV driver, ranging from a supply voltage of 5-8V, demonstrating sufficient electric field intensity (>10⁵ V/m) for the DEP focusing and separation electrodes.

AC Electro-Osmotic Flow Characterization

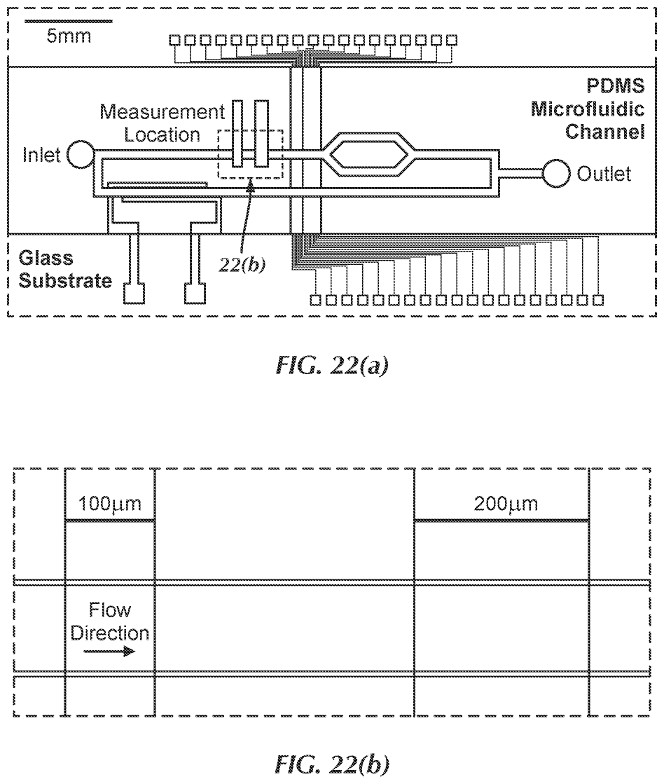

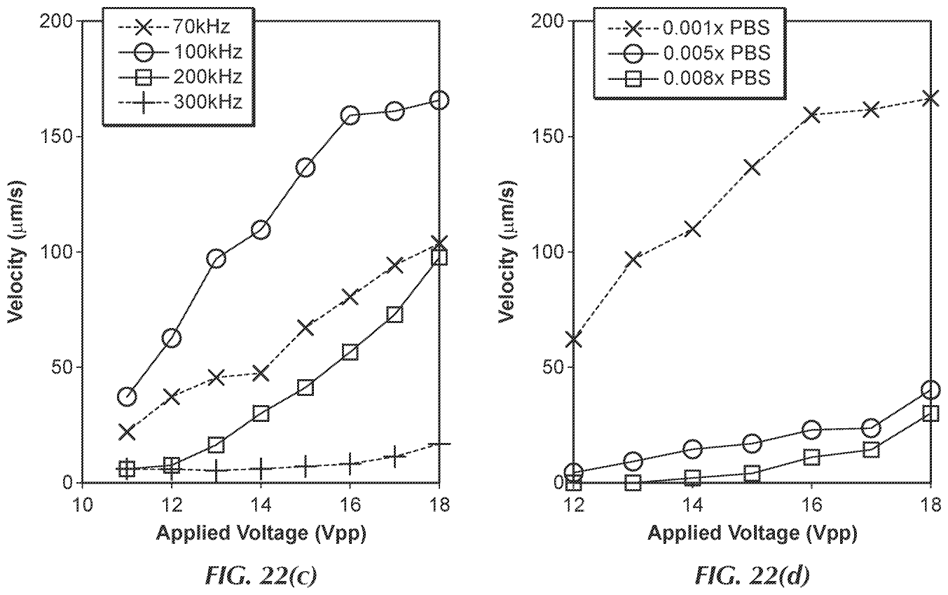

To characterize the AC-osmotic fluid flow, the electrodes are driven and then the fluid flow is measured on the other side of the microfluidic channel. This is to observe the bead velocity and to eliminate the effect of DEP on the beads, as shown in FIG. 21. As shown in FIG. 22(b), two floating electrodes, each with a width of 100 and 200 μm are fabricated far away from the AC osmosis electrodes to accurately measure the bulk fluid velocity. As described previously, the osmotic flow is dependent on the electrode width, separation, and fluid ionic concentration. Here, 0.001×PBS concentration is injected in the microfluidic channel to maximize the double layer diffusion length. To accurately measure the fluid velocity, 1 μm of polystyrene beads is mixed with the PBS solution. The small bead size is chosen to minimize the fluid drag effect while remaining observable under microscope.

In summary, the fluid driving capability is measured in following order. First, the 1 μm polystyrene beads (for example, Sigma-Aldrich LB11) is mixed with 0.001×PBS. Then, the fluid mixture is injected in the microfluidic channel. Next, a 100 kHz driving frequency is turned on from the CMOS chip with varying amplitude. Finally, the fluid velocity is determined by measuring the time that the 1 μm beads takes to travel across 100 and 200 μm electrodes respectively.

In summary, a balance between the ionic concentration, frequency, and the electrode dimension is experimentally optimized and summarized in FIGS. 21(a)-(d) and 22(a)-(d). Pattern #1 with a large electrode width of 15 μm appears to have the best fluid velocity with top speed reaching nearly 160 μm/s at 100 kHz. This translates into roughly 0.1 μL/min of fluid volume processing. The fluid processing speed is ample for cytometry and bio-molecular diagnostic applications.

Cell Focusing and Positioning with Engineered Fields

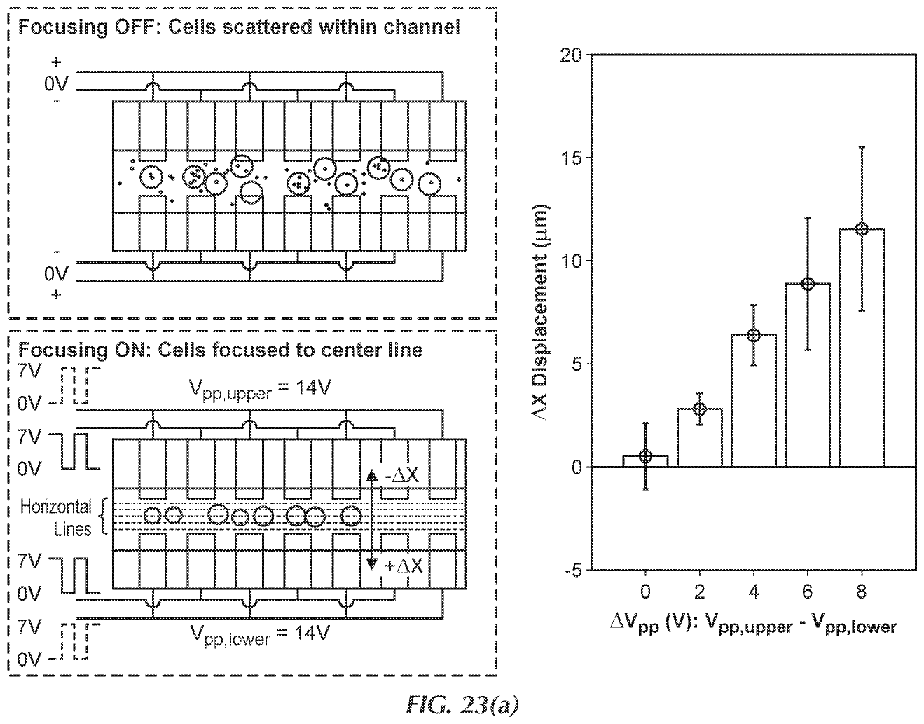

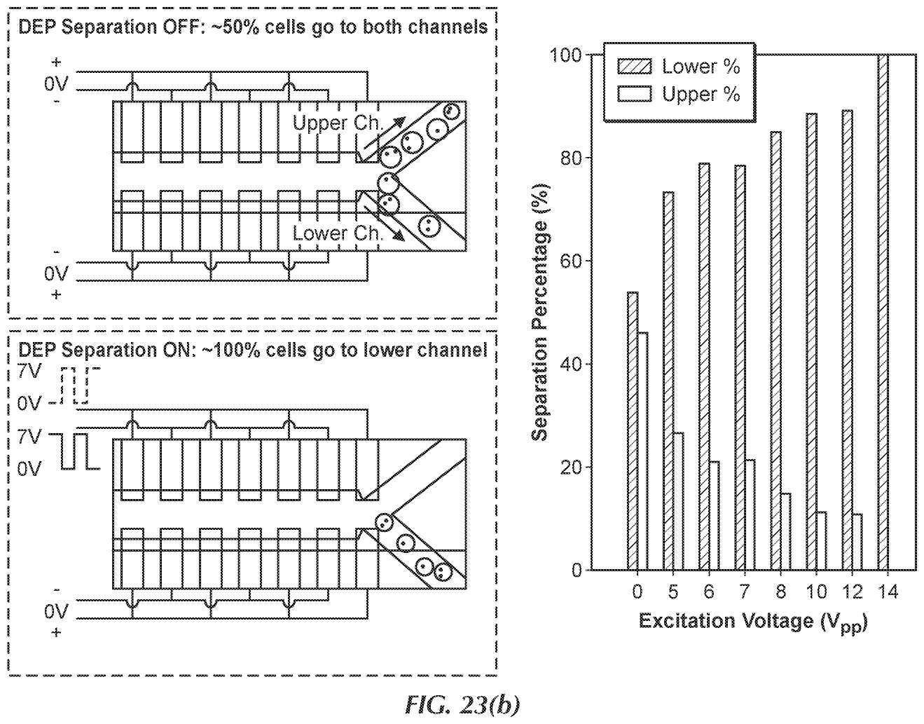

As described earlier, the chip architecture has the ability to engineer the electric fields within a cell flow to precisely control their position for sensing and subsequent separation. This functionality is characterized through electronic actuations and is calibrated with video from the microscope, as shown in FIG. 23(a). The cell focusing performance is then measured by recording the lateral displacements under various excitation conditions of a set of fifty 10 μm polystyrene beads (for example, Sigma-Aldrich Supelco 72986). FIG. 23(a)-(b) summarizes the electronic focusing performance under different excitation voltages at 100 kHz with error bars showing the standard deviations of each measuring set. In summary, the best focusing performance can be achieved under excitation voltage of 14 Vpp on both sides, where a standard deviation of only 2 μm of focusing error is observed. This value corresponds to less than 4% of the electrode separation gap of 50 μm, ensuring a consistent cytometry focusing performance. The proposed implementation significantly improves over the prior works that rely on hydrodynamic focusing that requires separate external pneumatic pumps.

Controlling the balance of the excitations on the two sides of electrodes, one can control the lateral displacement of the cells. As shown in FIG. 23(b), when the electrodes are turned off, beads are scattered randomly in the channel (50% going through both channels). After one side of the electrode is activated with 14 Vpp nearly 100% of the beads are pushed into the desired channel, seen in FIG. 23(b), demonstrating a reliable cell separation capability. Also shown is the measured percentage of separation purity under various voltage excitations showing a gradual enhancement with increasing voltage difference reaching up to almost 100%, as expected.

Cytometry Measurement Using Polystyrene Beads

The cytometry impedance measurement is first performed using two types of polystyrene beads: Sigma-Aldrich Supelco 72986 (10 μm) and 74491 (20 μm). First, the beads are diluted from the stock aqueous solution into 0.001×PBS solution buffer with dilution ratio between 1-0.1%. This ratio is experimentally obtained to prevent clogging in microfluidic while maintaining the best measurement visuals under microscope.

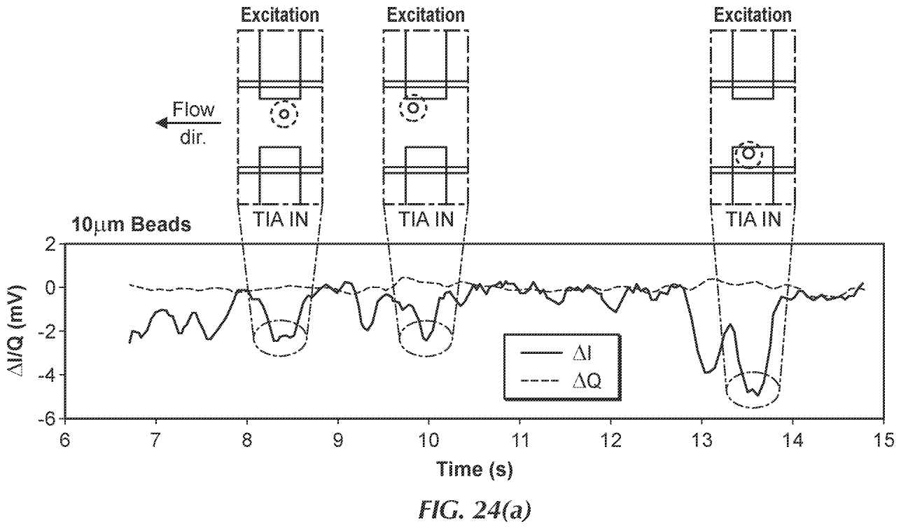

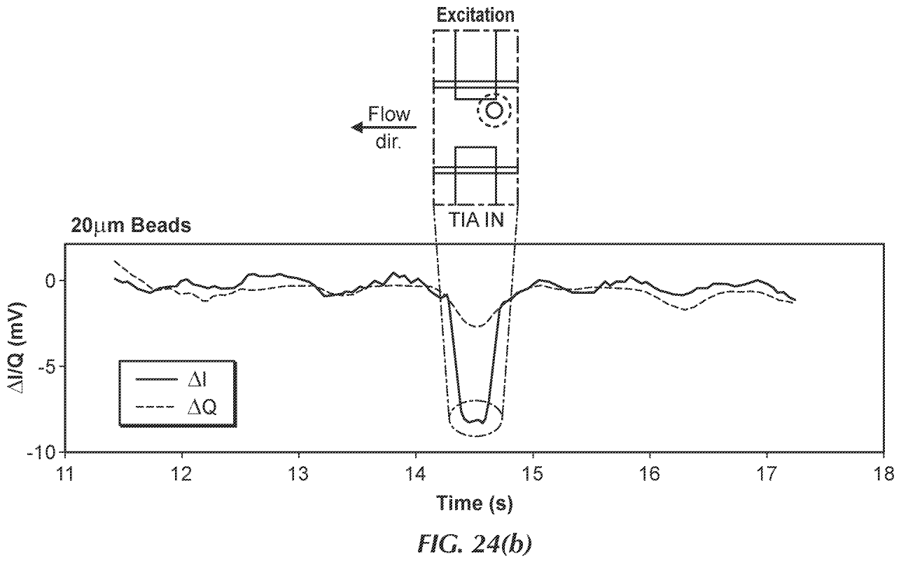

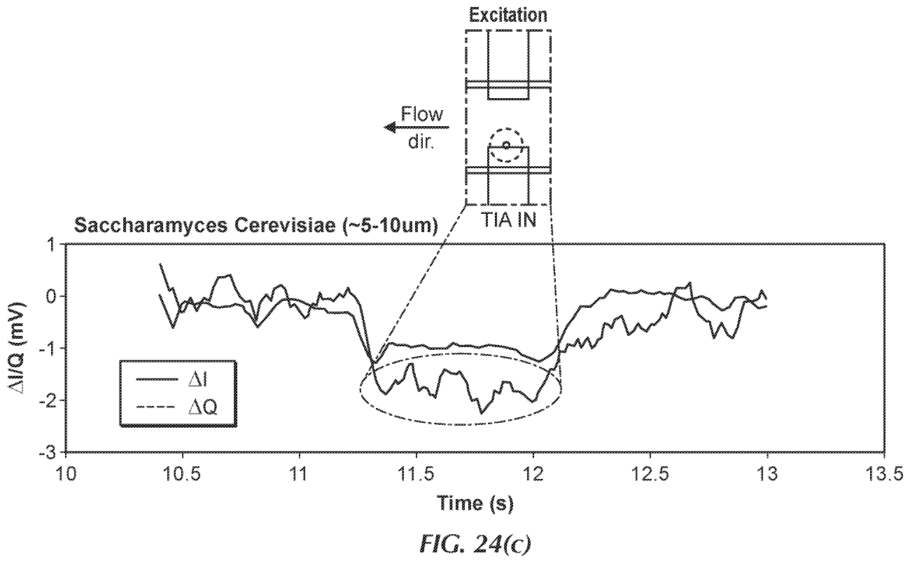

The diluted beads are then injected into the microfluidic channel and controlled electronically for accurate impedance measurements. FIGS. 24(a)-(b) demonstrate real-time measurement results of size 10 and 20 μm of beads under roughly 100 μm/s of flow rate. The average peak voltages are measured to be around 2 mV for 10 μm when channeled far away from the TIA input electrodes, and 4 mV when channel closer to TIA input electrodes. In addition, for a 20 μm polystyrene bead size, the signal is significantly larger when comparing against 10 μm, reaching nearly 8 mV of signal. This is close to the expected value, as the signal is proportional to the cube of the volume of the particle. The closeness of the cell flow to the electrodes can be controlled by the set of prior DEP electrodes as described previously. In addition, one can also estimate the velocity of the flow fully electronically by measuring the temporal separation of the peaks of a single bead as it flows through the various electrodes.

Cytometry Measurement of Yeast Cell

To demonstrate the cytometric sensing capabilities, the performance is measured with cultured yeast cells (for example, Saccharomyces cerevisiae). Similar to the previous sample preparation, the yeast cells are suspended in the same 0.001×PBS solution. The sizes of the yeast cells are reported in the range of 5-10 μm. Therefore, ensuring consistent focusing of the cell in the channel is a critical aspect in the measurement.

As shown in FIG. 24(c), when the cells are focused close to the TIA input electrodes, the cells demonstrate discernible signal levels (≈2 mV of signal), when compared against the solution baseline. The SNR is measured to be around 10 with the yeast cells (≈6 μm in diameter) focused close to the edge of the TIA input electrodes. Assuming, the signal level is roughly proportional to the volume of the cell size, the limit-of-detection (LOD) for the cytometry is approximately around 2.7 μm of cell size for SNR≈1.

Protein Measurement

Finally, protein bio-assay measurement capability is also disclosed herein. The measurement is performed on separate gold electrode platform on a silicon substrate and can be easily integrated in the same glass substrate as the AC osmosis and DEP system electrodes.

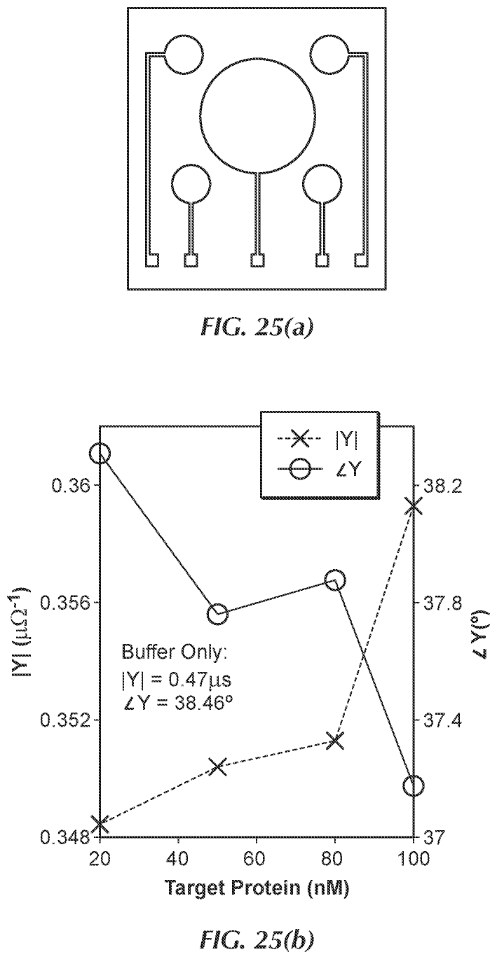

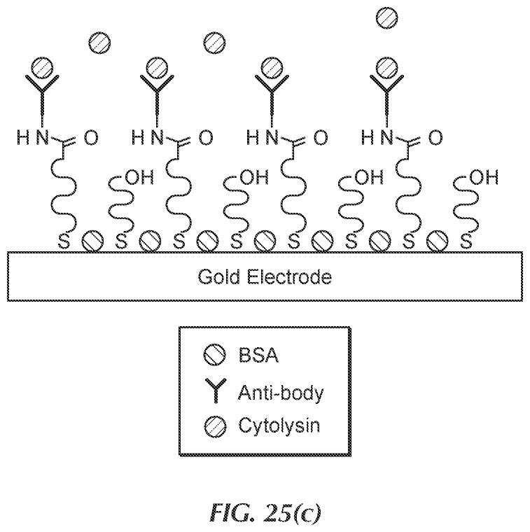

As shown in FIG. 25(a), the center excitation electrode has a diameter of 3 mm, with four TIA input electrodes (1 mm) located at the corners of the sensor. Standard label-free self-assembled monolayer (SAM) assay is then deployed on the custom fabricated gold electrodes.

First, the impedance gold electrodes are immersed in acetone, isopropanol (IPA), and Milli-Q water and then sonicated for 3 min. The electrodes were dried with a nitrogen stream and placed in a UV-O3 cleaner (for example, BioForce Nanoscience, USA) for 30 min. Finally, they were rinsed with IPA and dried with nitrogen stream. A mixed self-assembled monolayer (SAM) was formed ex-situ by incubating the gold electrodes overnight at room temperature with a mixed solution of alkanethiols (for example, 16-mercaptohexadecanoic acid (MHDA) and 11-mercaptoundecanol (MUOH)) in ethanol. The electrodes were then thoroughly rinsed with ethanol and dried with nitrogen stream.

Before applying the target cytolysin protein, the carboxylic group of MHDA were activated as carbodiimide esters by incubation of a mixed solution of EDC/sulfo-NHS (0.2 M/0.05 M) in MES buffer for one hour, and then rinsed with water and dried. The electrodes were incubated with a solution of antibody (50 μg/mL) in PBS buffer pH 7.4 overnight at room temperature. The electrodes were rinsed with PBS buffer to remove unbound antibody and dried with nitrogen stream. The uncovered gold surface was blocked with a 3% bovine serum albumin (BSA) to avoid non-specific bonding. The final surface chemistry is illustrated in FIG. 25(c) after surface activation.

The protein measurements are then performed with varying target cytolysin concentrations. FIG. 25(b) summarizes the measured admittance WRT different cytolysin concentrations at excitation frequency of 500 kHz. The figure shows the lowest detection concentration at 20 nM when comparing against the solution baseline.

Finally, the performance for the proposed system is summarized in the table in FIG. 19 against other state-of-the-art CMOS cytometry/protein biosensors. In particular, this is the first work that integrates the functionalities of bulk fluid process along with microfluidic cytometry and protein sensing in a single battery powered handheld device.

### CONCLUSION

As such, generally disclosed herein are embodiments for an approach to combine CMOS-based electrokinetic microfluidics with multi-modal cytometry and protein bio-essay sensing array platform for POC applications. Specifically, embodiments focus on realizing pneumatic-free microfluidic drivers with integrated cell actuation and impedance sensing capabilities for both cytometry and label-free protein sensing that are compatible with standard bioassay protocols. Shown herein were AC-osmotic bulk fluid flows with optimized electrode geometries and dynamic engineering of electric fields to precisely control, sense, and separate cells for cytometry. Demonstrated herein was 16-element impedance spectroscopic receivers on-chip for real-time cell sensing and protein assays. The approaches can be further optimized to yield

better performance but demonstrated overall herein are pathways toward pneumatic-free complex biosensing platforms and ultra-miniaturization for in-vitro and in-vivo applications.

It is understood that the above-described embodiments are only illustrative of the application of the principles of the present invention. The present invention may be embodied in other specific forms without departing from its spirit or essential characteristics. All changes that come within the meaning and range of equivalency of the claims are to be embraced within their scope. Thus, while the present invention has been fully described above with particularity and detail in connection with what is presently deemed to be the most practical and preferred embodiment of the invention, it will be apparent to those of ordinary skill in the art that numerous modifications may be made without departing from the principles and concepts of the invention as set forth in the claims.

1. A microfluidic bio-sensing system comprising:
at least one semiconductor chip configured to control at least one of electrokinetic fluid flow, cell manipulation and sensing, and bio-molecular sensing by utilizing at least one plurality of electrodes in a microfluidic channel.

2. The system of claim 1, wherein the semiconductor chip is configured to control voltage magnitudes on either side of the electrodes to synthesize an electric field in the microfluidic channel for electrokinetic fluid flow.

3. The system of claim 2, wherein the voltage is an AC voltage.

4. The system of claim 1, wherein the plurality of electrodes comprises an array of electrodes asymmetrical in geometry.

5. The system of claim 1, wherein the electrodes comprise at least one of gold, titanium, and chromium.

6. The system of claim 1, wherein the semiconductor chip is configured to control voltage magnitudes on either side of the microfluidic channel to synthesize an electric field in the microfluidic channel for cell focusing.

7. The system of claim 6, wherein the voltage is an AC voltage.

8. The system of claim 1, wherein the semiconductor chip is configured to create an asymmetric excitation on the plurality of electrodes for cell separation.

9. The system of claim 1, wherein a top portion of the plurality of electrodes is designated for voltage excitation and a bottom portion of the plurality of electrodes is connected to a receiver for cell sensing.

10. The system of claim 9, further comprising an impedance spectroscopy receiver configured to provide impedance measurements in real-time.

11. The system of claim 10, wherein the impedance spectroscopy receiver comprises a voltage excitation driver, transimpedance amplifier, and in-phase and quadrature mixer.

12. The system of claim 10, wherein the impedance spectroscopy receiver is configured for variable frequencies.

13. The system of claim 12, wherein the variable frequencies range from 10 KHz to 100 MHz.

14. The system of claim 1, wherein a first portion of the plurality of electrodes is designated for voltage excitation and a second portion of the plurality of electrodes is connected to a receiver for bio-molecular sensing, some electrodes of the plurality of electrodes being activated with probe molecules for binding with molecules of interest.

15. The system of claim 14, wherein the first portion of the electrodes comprises a center electrode and the second portion of the electrodes comprises four corner electrodes,
wherein the molecular of interest comprises at least one of proteins and nucleic acids, and/or
wherein the probe molecule comprises at least one of protein antibodies and nucleic-acid sequence probes.

16-17. (canceled)

18. The system of claim 1, further comprising a printed circuit board (PCB) to house the plurality of electrodes in the microfluidic channel and the semiconductor chip.

19. The system of claim 1, wherein the plurality of electrodes are embedded on a wafer,
wherein the semiconductor chip is a complementary metal oxide semiconductor (CMOS), and/or
wherein the microfluidic channel is made of polydimethylsiloxane (PDMS)

20-21. (canceled)

22. A scalable bio-sensing system, comprising an array of microfluidic controllers, each controller comprising:
at least one semiconductor chip configured to control at least one of electrokinetic fluid flow, cell manipulation and sensing, and bio-molecular sensing by utilizing at least one plurality of electrodes in a microfluidic channel.

23-57. (canceled)
